(19) United States
(12) Patent Application Publication
(10) Pub. No.: US 2017/0200723 A1
(43) Pub. Date: Jul. 13, 2017

(54) SEMICONDUCTOR DEVICES HAVING A GATE STRUCTURE AND A CONDUCTIVE LINE AND METHODS OF MANUFACTURING THE SAME

(71) Applicant: SAMSUNG ELECTRONICS CO., LTD., SUWON-SI (KR)

(72) Inventors: KI-SEOK LEE, Busan (KR); JOEONG-SEOP SHIM, Seoul (KR); DO-YEONG LEE, Gwangmyeong-Si (KR); CHAN-SIC YOON, Anyang-si (KR)

(21) Appl. No.: 15/340,598

(22) Filed: Nov. 1, 2016

(30) Foreign Application Priority Data
Jan. 7, 2016 (KR) 10-2016-0001868

(51) Int. Cl. H01L 27/108; H01L 29/06; H01L 23/528

(52) U.S. Cl. CPC H01L 27/10814; H01L 23/528; H01L 29/0649

(57) ABSTRACT

A semiconductor device includes an active pattern. A first source or drain region and a second source or drain region are formed at upper portions of the active pattern. The first source or drain region and the second source or drain region are each disposed adjacent to the gate structure. The gate structure is disposed between the first source or drain region and the second source or drain region. A conductive line is electrically connected to the first source or drain region, the conductive line including a first portion and a second portion. A width of the first portion is greater than a width of the second portion. The width of the first and second portions of the conductive line is measured along a first direction in plan view. A conductive contact is electrically connected to the second source or drain region.

### CROSS-REFERENCE TO RELATED APPLICATION

This application claims priority under 35 U.S.C. §119 to Korean Patent Application No. 10-2016-0001868, filed on Jan. 7, 2016, in the Korean Intellectual Property Office (KIPO), the content of which is incorporated by reference herein in its entirety.

### TECHNICAL FIELD

Example embodiments of the inventive concept relate to semiconductor devices and methods of manufacturing the same. More particularly, example embodiments of the inventive concept relate to semiconductor devices including a gate structure and a conductive line, and methods of manufacturing the same.

### DISCUSSION OF THE RELATED ART

As a semiconductor device, for example, a dynamic random access memory (DRAM) device, becomes smaller in size with a greater number of circuit elements, a distance between the conductive structures of the semiconductor device may be reduced. The conductive structure of the semiconductor device may include wirings, contacts, etc. In addition, an aspect ratio of the conductive structure may be increased when the size of the semiconductor device decreases. When the size of the semiconductor device decreases, the conductive structure may be more prone to malfunction, and a contact resistance of the semiconductor device may increase.

### SUMMARY

According to an example embodiment of the inventive concept, a semiconductor device has enhanced electrical and mechanical properties.

According to an example embodiment of the inventive concept, a method of manufacturing a semiconductor device may be used to manufacture a semiconductor device having enhanced electrical and mechanical properties.

According to an example embodiment of the inventive concept, a semiconductor device includes an active pattern. A first source or drain region and a second source or drain region are formed at upper portions of the active pattern. The first source or drain region and the second source or drain region are each disposed adjacent to the gate structure. The gate structure is disposed between the first source or drain region and the second source or drain region. A conductive line is electrically connected to the first source or drain region, the conductive line including a first portion and a second portion. A width of the first portion is greater than a width of the second portion. The width of the first and second portions of the conductive line is measured along a first direction in plan view. A conductive contact is electrically connected to the second source or drain region.

According to an example embodiment of the inventive concept, a semiconductor device includes a substrate. An isolation layer is disposed on the substrate. A plurality of active patterns protrude from the substrate, the active patterns of the plurality of active patterns being spaced apart from each other by the isolation layer. A plurality of gate structures are buried in the isolation layer and are buried in the active patterns, the plurality of gate structures extending in a first direction parallel to a plane of a top surface of the substrate. First source or drain regions and second source or drain regions are formed at upper portions of the plurality of active patterns, the first source or drain regions and the second source or drain regions being separated from each other by the plurality of gate structures. A plurality of conductive lines are electrically connected to the first source or drain regions, the plurality of conductive lines extending in a second direction parallel to the top surface of the substrate. The second direction crosses the first direction, and each of the plurality of conductive lines includes enlarged portions and straight portions. The enlarged portions protrude in the first direction and are wider than the straight portions in the first direction. A plurality of conductive contacts are electrically connected to the second source or drain regions of the plurality of active patterns, the plurality of conductive contacts being disposed adjacent to the straight portions of the plurality of conductive lines.

According to an example embodiment of the inventive concept, a semiconductor device includes an active pattern. The active pattern includes a first source or drain region and at least two second source or drain regions. The first source or drain region is disposed between the at least two second source or drain regions. A gate structure is disposed on the active pattern. The first source or drain region and one of the at least two second source or drain regions are separated from each other by the gate structure. A conductive line is electrically connected to the first source or drain region. The conductive line includes first portions and second portions, the first portions being wider than the second portions in a first direction in plan view. First and second portions of the conductive line are alternatively arranged along a second direction that crosses the first direction in the plan view. A conductive contact is electrically connected to one of the at least two second source or drain regions.

### BRIEF DESCRIPTION OF THE DRAWINGS

The above and other features of example embodiments of the inventive concept are described in detail below in conjunction with the accompanying drawings, in which:

FIG. 1 is a top plan view illustrating a semiconductor device, according to an example embodiment of the inventive concept;

FIGS. 2 to 4 are cross-sectional views of the semiconductor device of FIG. 1, according to an example embodiment of the inventive concept;

FIGS. 5 to 34 are top plan views and cross-sectional views illustrating a method of manufacturing a semiconductor device, according to an example embodiment of the inventive concept;

FIGS. 35 to 47 are top plan views and cross-sectional views illustrating a mask fabricating process for forming a conductive line, according to an example embodiment of the inventive concept;

FIGS. 48 to 53 are top plan views and cross-sectional views illustrating a mask fabricating process for forming a conductive line, according to an example embodiment of the inventive concept;

FIGS. 54 and 55 are cross-sectional views illustrating a semiconductor device, according to an example embodiment of the inventive concept; and

FIGS. 56 and 57 are cross-sectional views illustrating a semiconductor device, according to an example embodiment of the inventive concept.

### DETAILED DESCRIPTION OF THE EMBODIMENTS

Example embodiments of the inventive concept will now be described more fully hereinafter with reference to the accompanying drawings. The inventive concept may, however, be embodied in different forms and should not be construed as limited to the example embodiments set forth herein. When an element is described as being disposed on another element, intervening elements may be disposed therebetween.

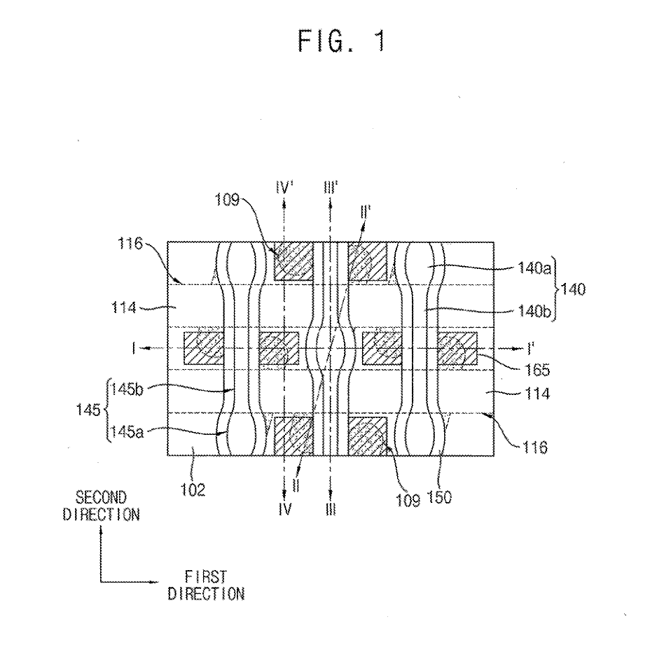

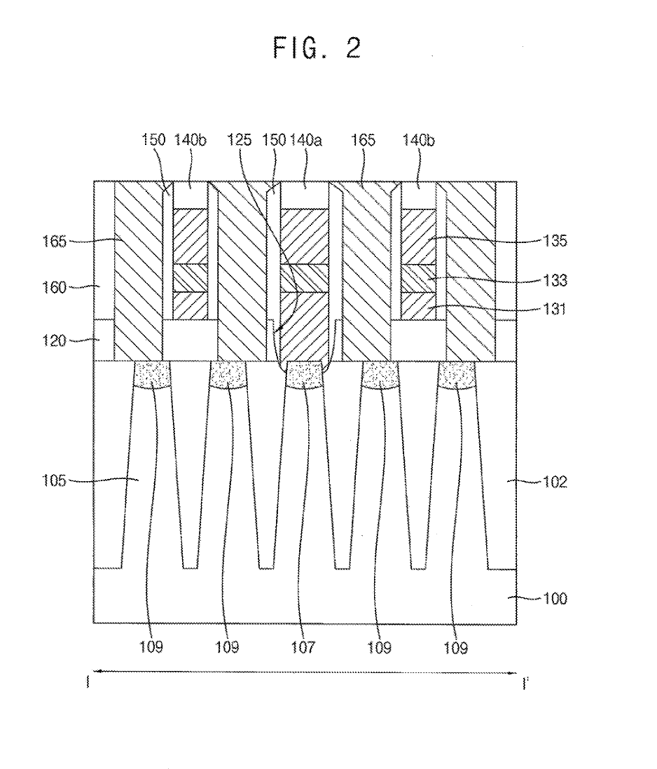

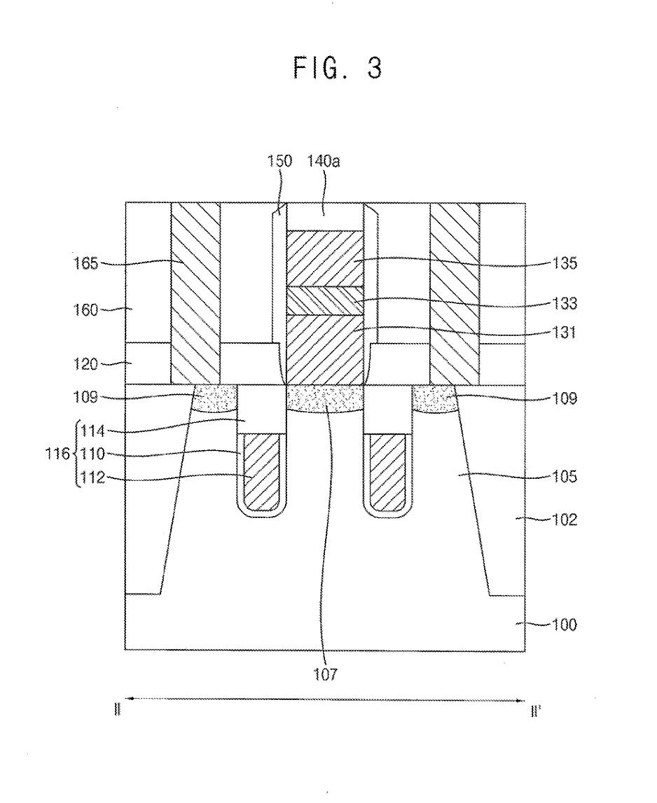

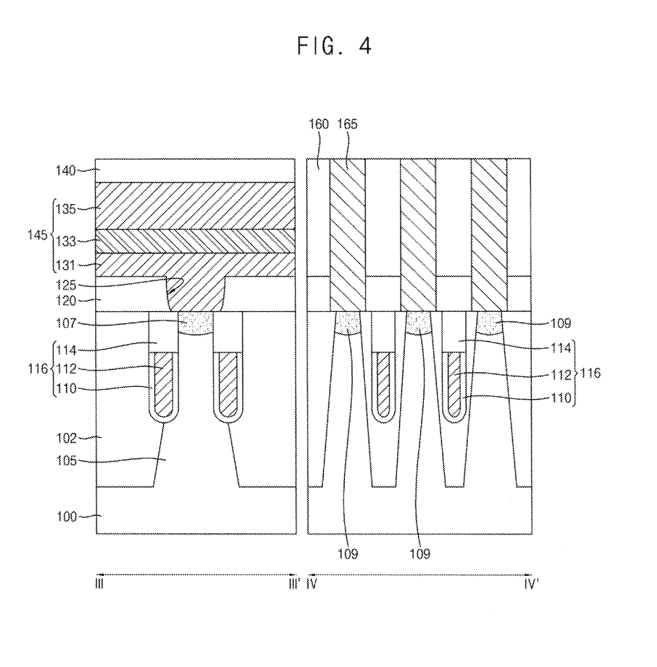

FIG. 1 is a top plan view illustrating a semiconductor device, according to an example embodiment of the inventive concept. FIGS. 2 and 3 are cross-sectional views taken along lines I-I′ and II-II′ of FIG. 1, respectively. FIG. 4 includes cross-sectional views taken along lines III-III′ and IV-IV' of in FIG. 1. FIGS. 1 to 4 illustrate a semiconductor device including a buried cell array transistor (BCAT) structure.

In FIGS. 1 to 4, two directions (e.g., a first direction and a second direction) are substantially parallel to a top planar surface of a substrate. In addition, the first and second directions may be perpendicular to each other. The first and second directions are illustrated by arrows in the figures. It is understood that the first direction may also be a direction that is opposite to that of the arrow corresponding to the first direction in the drawings. In addition, the second direction may also be a direction that is opposite to that of the arrow corresponding to the second direction in the drawings.

Referring to FIGS. 1 to 4, the semiconductor device may include a substrate 100, active patterns 105 protruding from the substrate 100, gate structures 116 extending through upper portions of the active patterns 105, a conductive line 145 extending on the active patterns 105, and a conductive contact 165 disposed on an upper surface of the active patterns 105.

The substrate 100 may include silicon, germanium, silicon-germanium or a group III-V compound such as GaP, GaAs, GaSb, etc. In an example embodiment of the inventive concept, the substrate 100 may be a silicon-on-insulator (SOI) substrate or a germanium-on-insulator (GOI) substrate.

An active pattern 105 may be formed from an upper portion of the substrate 100. The active pattern 105 may have an island shape confined by an isolation layer 102.

In an example embodiment of the inventive concept, the active pattern 105 may extend in a direction that forms an angle (e.g., a predetermined angle) with respect to the first direction or the second direction. For example, the active pattern 105 may form an acute angle with respect to the first or second directions. The plurality of the active patterns 105 may be arranged in the first and second directions. The number of the active patterns 105 in a unit area of the substrate 100 (e.g., density of the active patterns 105) may be increased while maintaining a desired or predetermined distance between neighboring active patterns 105 by arranging the active patterns 105.

The isolation layer 102 may include an insulation material such as a silicon oxide.

The gate structure 116 may be buried in an upper portion of the active pattern 105. For example, the gate structure 116 may fill a gate trench formed in the active pattern 105. In an example embodiment of the inventive concept, the gate structure 116 may be formed through upper portions of the active patterns 105 and the isolation layer 102, and may extend in the first direction. A plurality of the gate structures 116 may be arranged along the second direction.

The gate structure 116 may include a gate insulation pattern 110, a gate electrode 112 and a gate mask 114, sequentially stacked on a bottom of the gate trench. For example, the gate insulation pattern 110 may be formed on the bottom of the gate trench, and the gate electrode 112 may be formed on the gate insulation pattern 110 to fill a lower portion of the gate trench. The gate mask 114 may be disposed on both the gate insulation pattern 110 and the gate electrode 112. The gate mask 114 may cap an upper portion of the gate trench.

The gate insulation pattern 110 may include, for example, a silicon oxide or a metal oxide. The gate electrode 112 may include, for example, a metal nitride such as titanium nitride, tantalum nitride or tungsten nitride, and/or a metal such as titanium, tantalum, aluminum or tungsten. The gate mask 114 may include, for example, silicon nitride.

In an example embodiment of the inventive concept, two gate structures 116 may be formed in each active pattern 105. Accordingly, as shown in FIG. 3, an upper portion of the active pattern 105 may include a central portion between the two gate structures 116 and two peripheral portions adjacent to the two gate structures 116. The central portion of the active pattern 105 may be disposed between the two peripheral portions.

An impurity region may be formed at the upper portion of the active pattern 105 adjacent to the gate structures 116. In an example embodiment of the inventive concept, a first impurity region 107 may be formed at the central portion of the upper portion of the active pattern 105, and second impurity regions 109 may be formed at each of the peripheral portions of the upper portion of the active pattern 105. For example, one first impurity region 107 and two second impurity regions 109 may be included within one active pattern 105.

The first and second impurity regions 107 and 109 may serve as first and second source/drain regions, respectively, of the semiconductor device.

The conductive line 145 may extend in the second direction on the active patterns 105 and the isolation layer 102. A plurality of the conductive lines 145 may be arranged along the first direction. In an example embodiment of the inventive concept, the conductive line 145 may be electrically connected to the first impurity region 107. For example, the conductive line 145 may serve as a bit line of the semiconductor device.

The conductive line 145 may include a first conductive pattern 131, a barrier conductive pattern 133 and a second conductive pattern 135 sequentially stacked on the first impurity region 107 and/or the active pattern 105. A mask pattern 140 may be disposed on the second conductive pattern 135. The first conductive pattern 131 of the conductive line 145 may be in contact with and/or electrically connected to the first impurity region 107.

The first conductive pattern 131 may include doped polysilicon. The barrier conductive pattern 133 may include a metal nitride or a metal silicide nitride. For example, the barrier conductive pattern 133 may include titanium nitride (TiN), titanium silicide nitride (TiSiN), tantalum nitride (TaN) or tantalum silicide nitride (TaSiN). The second conductive pattern 135 may include a metal such as tungsten or copper. The mask pattern 140 may include, for example, silicon nitride.

In an example embodiment of the inventive concept, the conductive line 145 may include a first portion 145a and a second portion 145b having a different width from the first portion 145a (e.g., widths in the first direction). The first portion 145a may be wider than the second portion 145b. The first portion 145a may have a shape of, for example, a convex pattern or an embossed pattern in plan view.

In an example embodiment of the inventive concept, a plurality of the first portions 145a and the second portions 145b may be alternately repeated in one conductive line 145. Thus, a width of the conductive line 145 may increase and decrease repeatedly along the second direction.

In an example embodiment of the inventive concept, the first portions 145a included in the different conductive lines 145 may be arranged in a staggered or zigzag configuration. For example, as illustrated in FIG. 1, the first portions 145a included in two neighboring conductive lines 145 may face away from each other in the first direction. For example, a first portion 145a of a first conductive line 145 may face a second portion 145b of a neighboring second conductive line 145 in the first direction.

The first portion 145a included in the conductive line 145 may overlap the first impurity region 107. In an example embodiment of the inventive concept, the conductive line 145 may be in contact with and/or electrically connected to the first impurity region 107 via the first portion 145a.

In an example embodiment of the inventive concept, as illustrated in FIG. 3, a first insulating interlayer 120 and a second insulating interlayer 160 may be formed on the active pattern 105 and the isolation layer 102. The first portion 145a of the conductive line 145 may extend through the second and first insulating interlayers 160 and 120 to contact the first impurity region 107.

The first and second insulating interlayers 120 and 160 may include a silicon oxide such as plasma enhanced oxide (PEOX), tetraethyl orthosilicate (TEOS), silicate glass, or the like, or a low dielectric (low-k) oxide such as siloxane or silsesquioxane.

As illustrated in FIG. 1, the second portion 145b included in the conductive line 145 may be adjacent to the second impurity region 109 in plan view. In an example embodiment of the inventive concept, the second portion 145b of a conductive line 145 may be disposed between two neighboring second impurity regions 109 included in different active patterns 105. Accordingly, the second impurity region 109 may be exposed by the second portion 145b in plan view. For example, since the second portion 145b of a conductive line 145 might only partially overlap with the second impurity regions 109 adjacent thereto, the portions of the second impurity regions 109 that do not overlap the second portion 145b may be exposed to, for example, the conductive contacts 165.

The mask pattern 140 may include a first portion 140a and a second portion 140b based on the construction (e.g., shape or structure) of the conductive line 145 as described above.

A spacer 150 may be formed on a sidewall of the conductive line 145. The spacer 150 may include, for example, silicon nitride or silicon oxynitride. The conductive line 145 and the conductive contact 165 may be insulated and spaced apart from each other by the spacer 150.

The conductive contact 165 may extend through the second and first insulating interlayers 160 and 120, and may be in contact with and/or electrically connected to the second impurity region 109.

As described above, the second portion 145b of a conductive line 145 which may have a relatively small width, when compared to the first portion 145a of the conductive line 145, may be disposed around the second impurity region 109. Thus, an area (e.g., an exposed area) of the second impurity region 109 which may be in contact with the conductive contact 165 may be increased. Therefore, a contact resistance between the conductive contact 165 and the second impurity region 109 may be reduced. In addition, a mis-alignment of the conductive contact 165 may be avoided.

In an example embodiment of the inventive concept, a silicide layer including a metal silicide may be formed on each of the first impurity region 107 and the second impurity region 109. In this case, the conductive contact 165 and the conductive line 145 may be in contact with the silicide layer of the first impurity region 107 and the second impurity region 109. For example, the silicide layer of the first impurity region 107 and the second impurity region 109 may serve as a source/drain region together with the impurity regions 107 and 109.

In an example embodiment of the inventive concept, as illustrated in FIG. 2, the conductive contact 165 may be self-aligned (e.g., aligned) with the spacer 150. In this case, the conductive contact 165 may be in contact with a sidewall of the spacer 150.

According to an example embodiment of the inventive concept as described above, the first portion 145a of the conductive line 145, which may have a relatively large width, may be connected to the first impurity region 107 (or the first source/drain region) so that an electrical resistance through the conductive line 145 may be reduced. The second portion 145b of the conductive line 145, having a relatively small width, may be adjacent to the second impurity region 109 so that a contact area between the conductive contact 165 and the second impurity region 109 (or the second source/drain region) may be increased. The contact area between the conductive contact 165 and the second impurity region 109 may be large since the portion of the second impurity region 109 that is not overlapped by the second portion 145b may contact or be electrically connected to the conductive contact 165.

Additionally, a width of the conductive line 145 may increase and decrease repeatedly so the conductive line 14 may have an increased mechanical stability. For example, mechanical failure of the conductive line 145, such as collapse, leaning, bending, etc., may be prevented or reduced due to the increasing and decreasing width of the conductive line 145. For example, the first portions 145a having the relatively large width may serve as supporting portions of the conductive line 145.

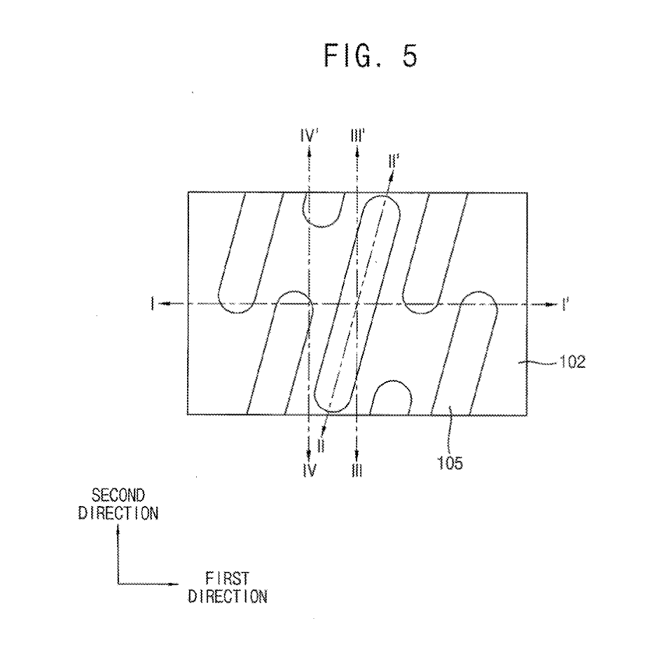

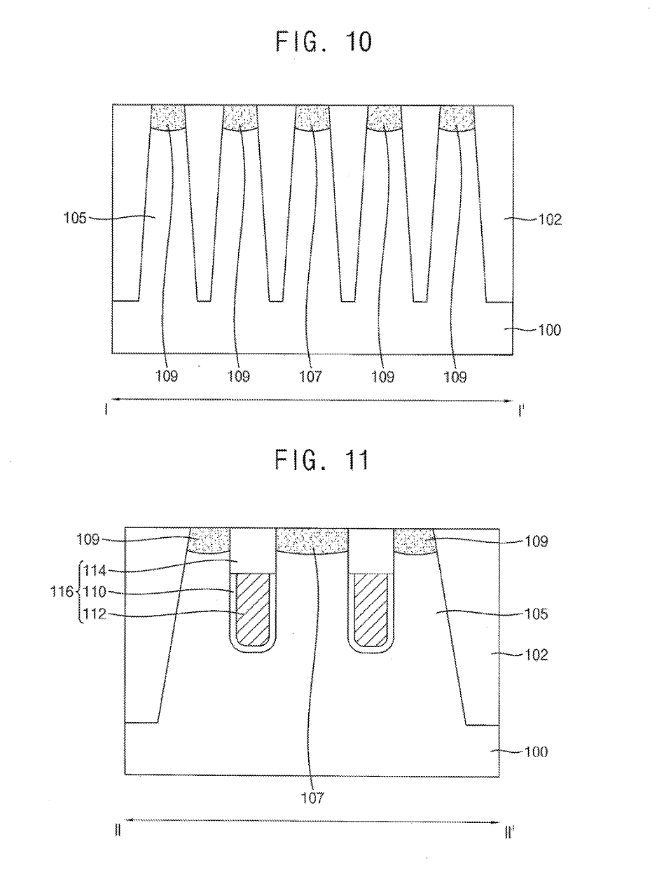

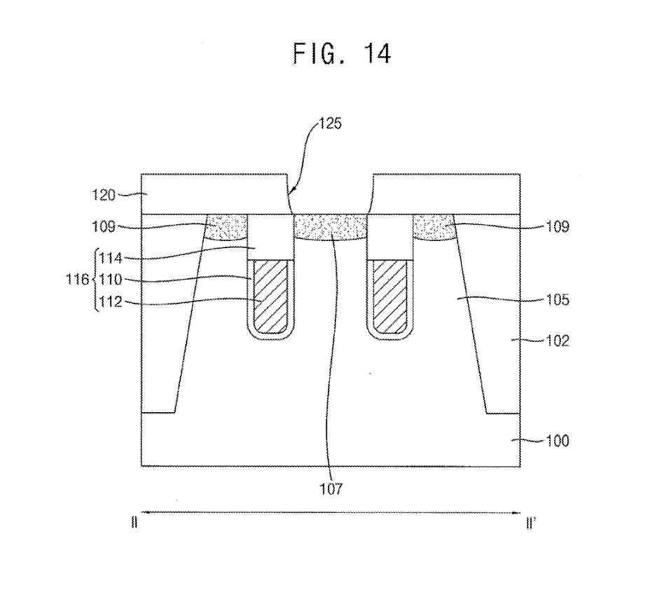

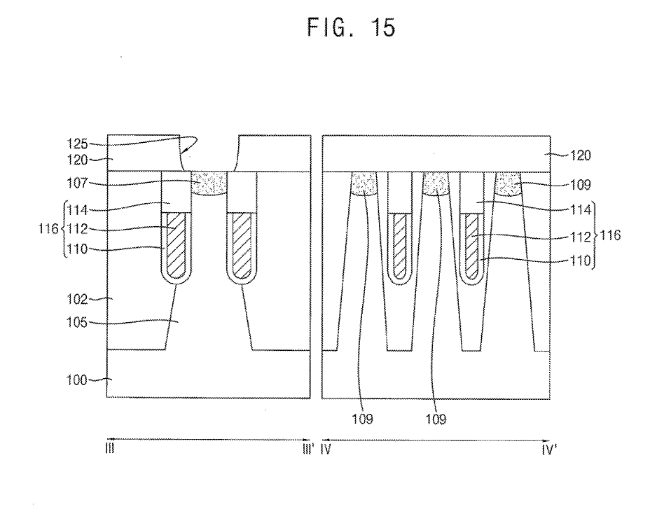

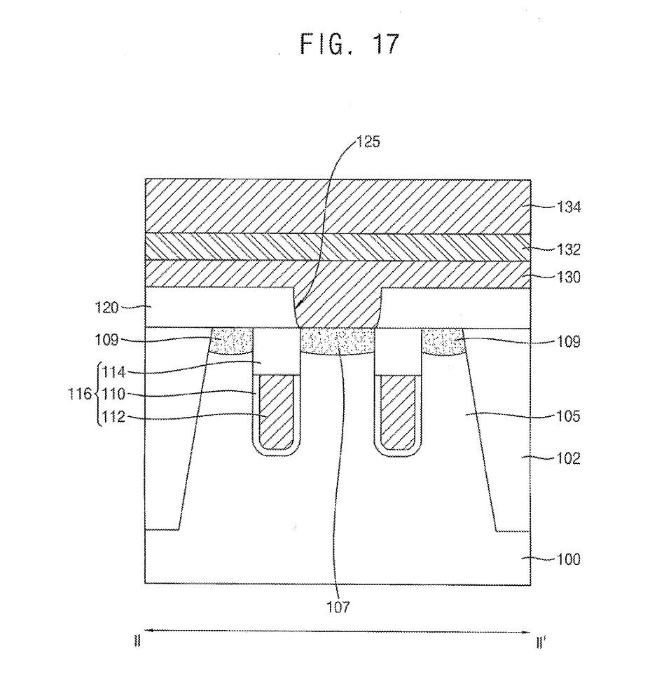

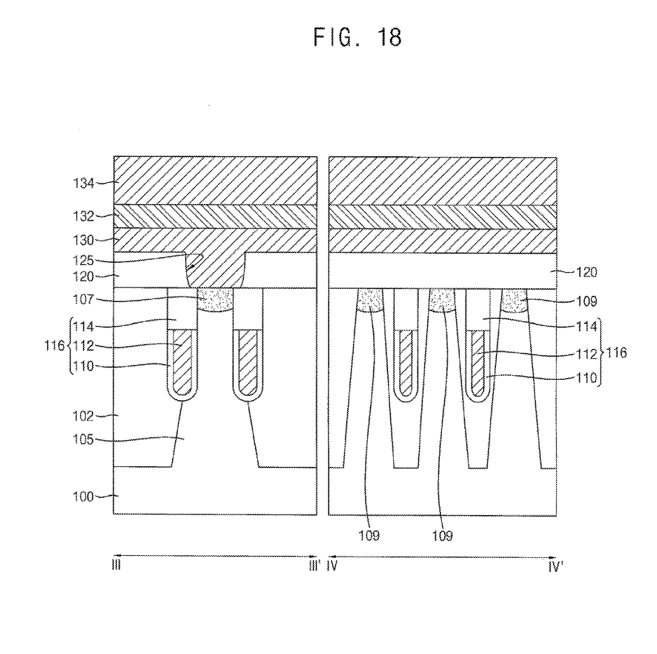

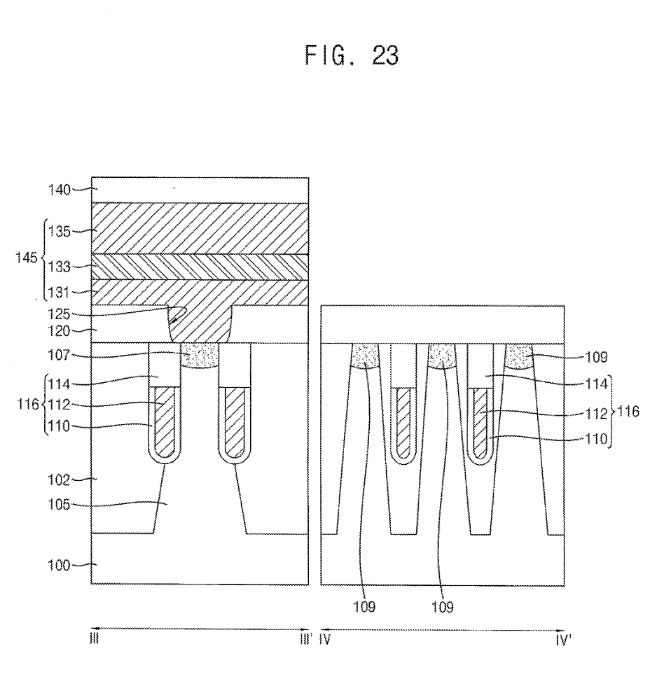

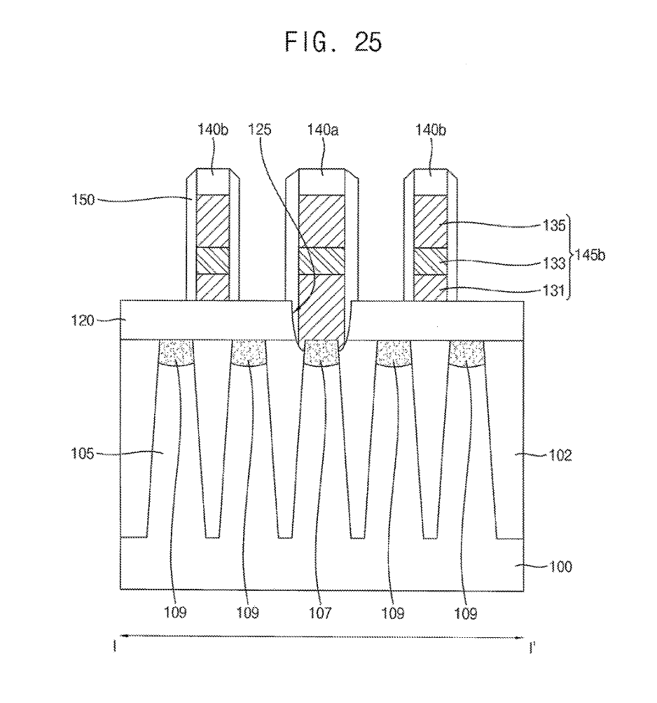

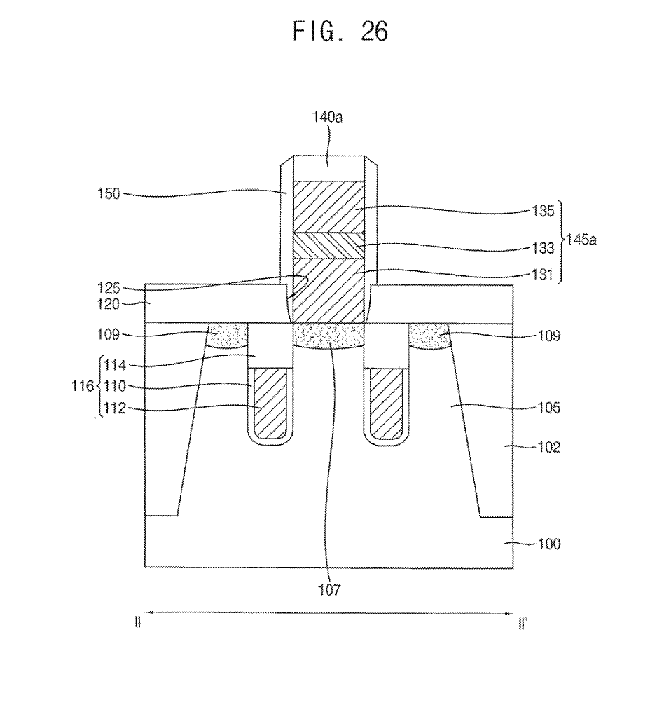

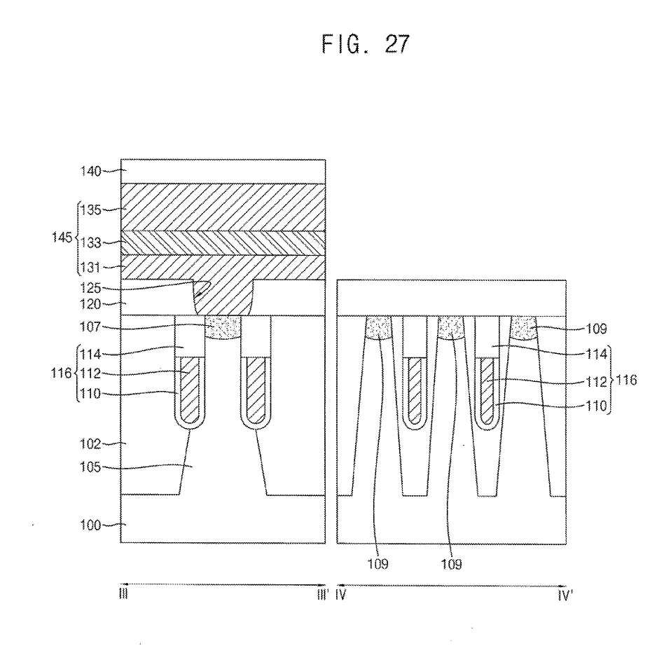

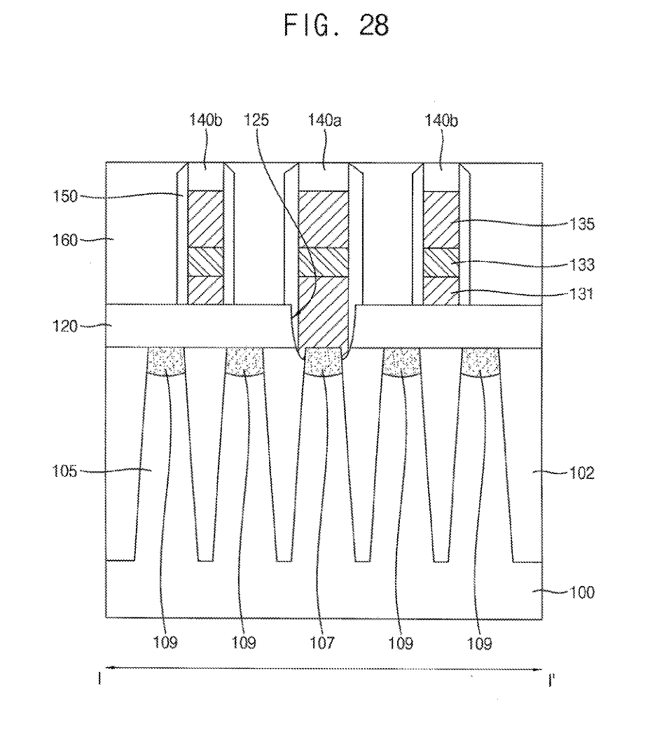

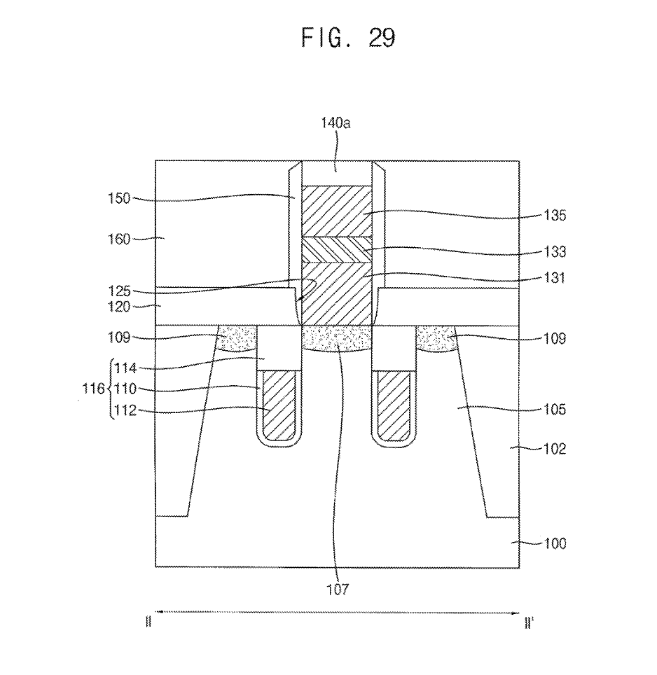

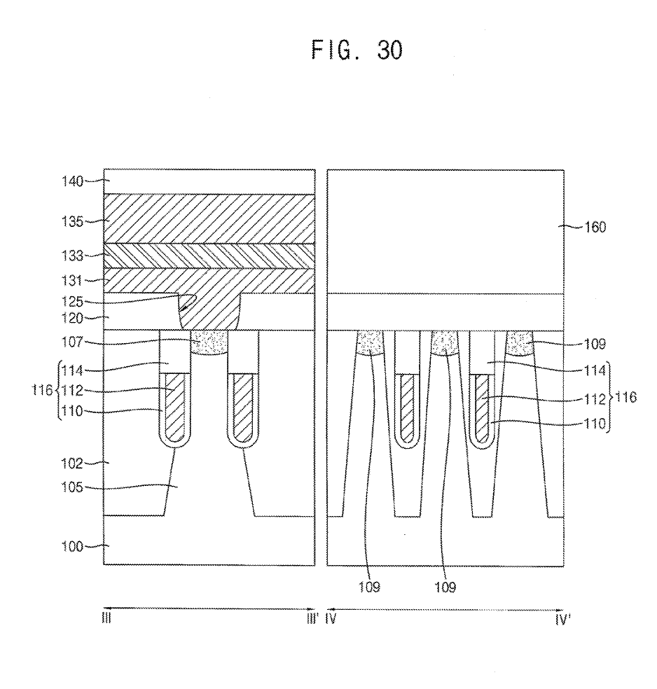

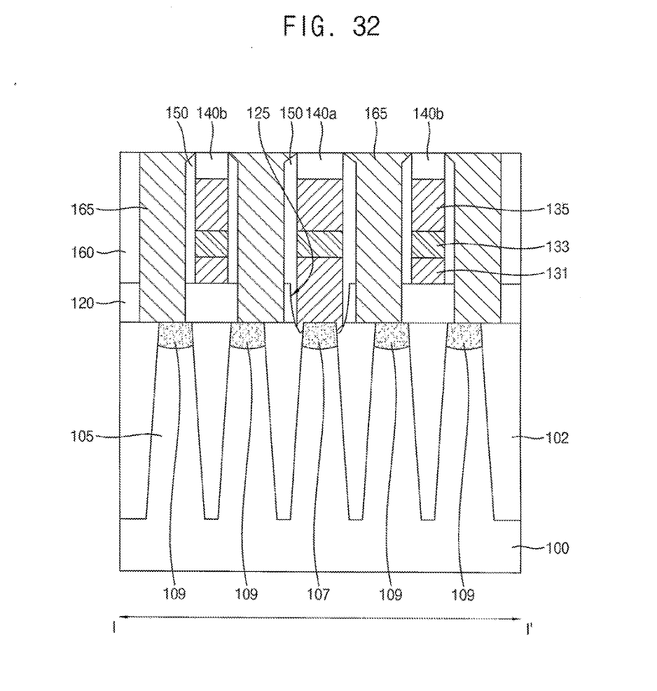

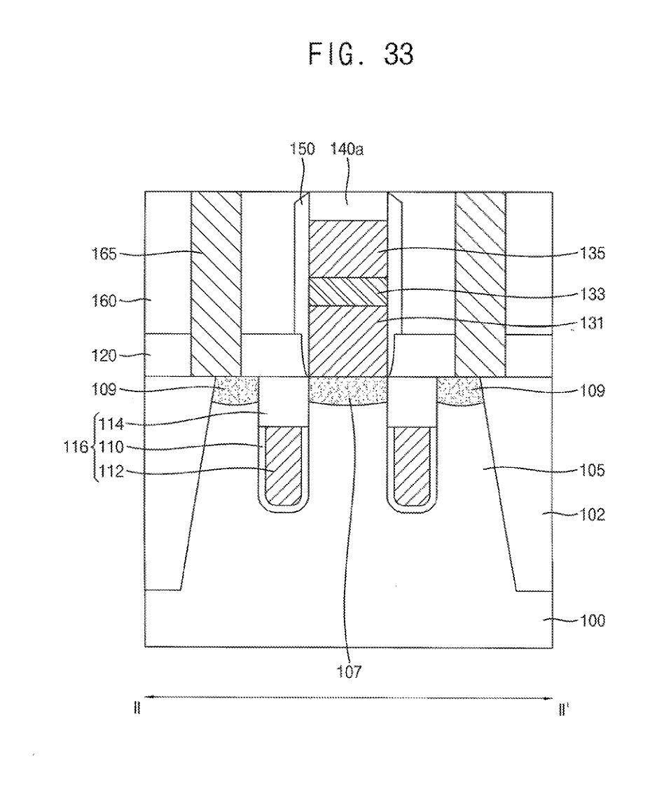

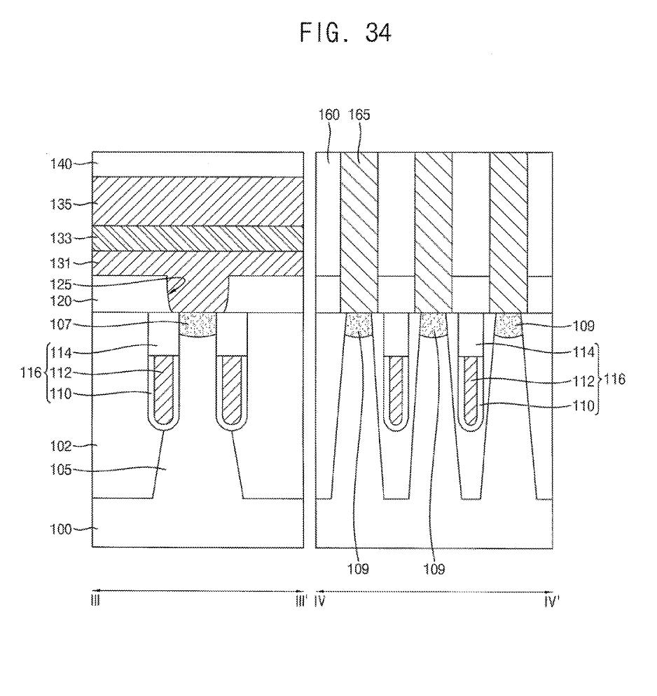

FIGS. 5 to 34 are top plan views and cross-sectional views of a method of manufacturing a semiconductor device, according to an example embodiment of the inventive concept. FIGS. 5 to 34 illustrate, for example, a method of manufacturing the semiconductor device of FIGS. 1 to 4.

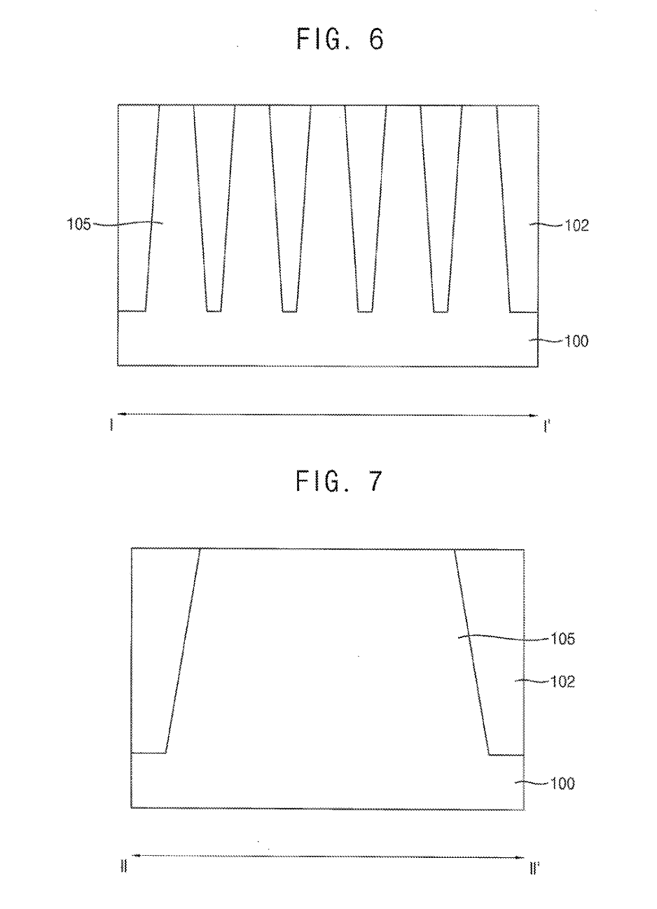

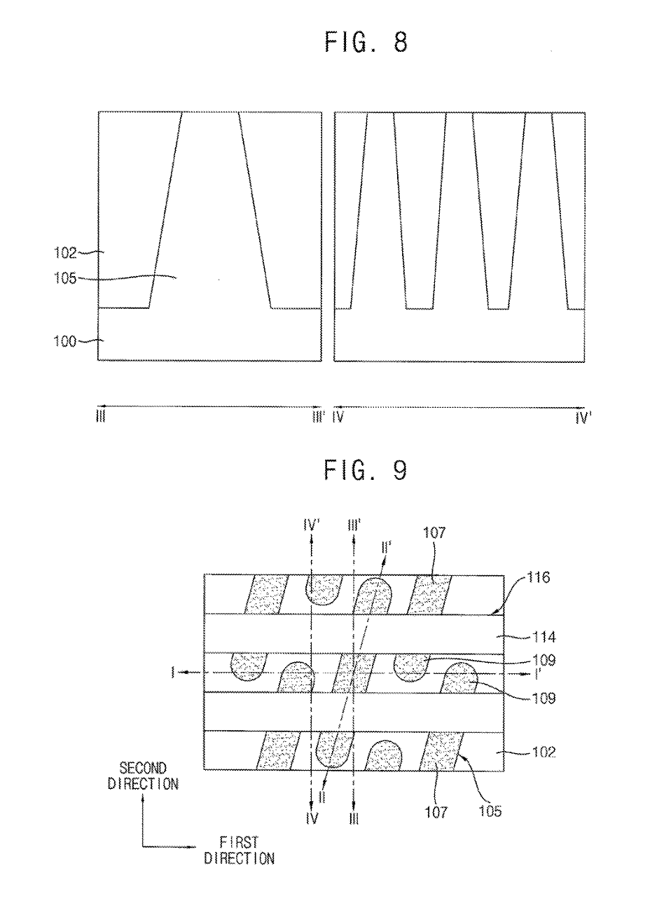

In more detail, FIGS. 5, 9, 19, 20 24 and 31 are top plan views illustrating stages of the method. FIGS. 6, 10, 13, 16, 21, 25, 28 and 32 are cross-sectional views taken along a line I-I′ indicated in the top plan views. FIGS. 7, 11, 14, 17, 22, 26, 29 and 33 are cross-sectional views taken along a line II-II′ indicated in the top plan views. Each of FIGS. 8, 12, 15, 18, 23, 27, 30 and 34 includes cross-sectional views taken along lines III-III′ and IV-IV′ indicated in the top plan views.

Referring to FIGS. 5 to 8, an isolation layer 102 may be formed on a substrate 100 to define active patterns 105.

The substrate 100 may include silicon, germanium, silicon-germanium or a group III-V compound such as GaP, GaAs, GaSb, etc. In an example embodiment of the inventive concept, the substrate 100 may be an SOI substrate or a GOI substrate.

In an example embodiment of the inventive concept, the isolation layer 102 and the active pattern 105 may be formed by a shallow trench isolation (STI) process. For example, a hard mask may be formed on a top surface of the substrate 100. An upper portion of the substrate 100 may be partially removed by an anisotropic etching process using the hard mask as an etching mask such that an isolation trench may be formed.

An insulation layer filling the isolation trench may be formed on the substrate 100 and the hard mask. The insulation layer and the hard mask may be planarized by, for example, a chemical mechanical polish (CMP) process until a top surface of the active pattern 105 is exposed to form the isolation layer 102. The isolation layer 102 may include, for example, a silicon oxide.

A plurality of the active patterns 105 may be formed to be spaced apart from each other by the isolation layer 102. As illustrated in FIG. 5, each active pattern 105 may extend in a direction that forms an angle (e.g., a predetermined angle) with respect to the first direction or the second. For example, the active pattern 105 may form an acute angle with respect to the first or second directions. The plurality of the active patterns 105 may be arranged along the first and second directions.

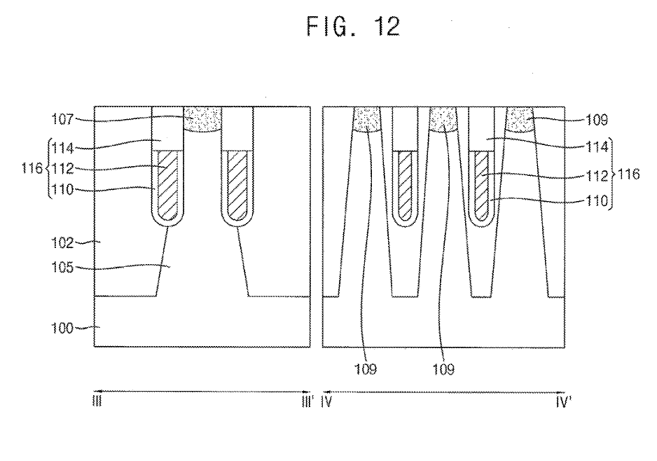

Referring to FIGS. 9 and 12, a gate structure 116 being buried and extending in the active patterns 105 may be formed.

In an example embodiment of the inventive concept, upper portions of the isolation layer 102 and the active patterns 105 may be etched to form a gate trench. The gate trench may be formed, for example, through the upper portions of the isolation layer 102 and the active patterns 105. In addition, the gate trench may extend in the first direction. A plurality of the gate trenches may be formed along the second direction. In an example embodiment of the inventive concept, two gate trenches may be formed in each active pattern 105.

A gate insulation layer may be formed on an inner wall of the gate trench. The gate insulation layer may be formed, for example, by performing a thermal oxidation process on a surface of the active pattern 105 exposed by the gate trench. Alternatively, the gate insulation layer may be formed by depositing a silicon oxide or a metal oxide on the surface of the active pattern 105 by, for example, a chemical vapor deposition (CVD) process.

A gate conductive layer filling the gate trench to a predetermined level may be formed on the gate insulation layer. The gate conductive layer and/or the gate insulation layer may be planarized by a CMP process until the top surface of the active pattern 105 may be exposed. Upper portions of the gate conductive layer and the gate insulation layer formed in the gate trench may be partially removed by an etch-back process. Accordingly, a gate insulation pattern 110 and a gate electrode 112 filling a lower portion of the gate trench may be formed.

The gate conductive layer may include a metal and/or a metal nitride by an atomic layer deposition (ALD) process, a sputtering process, etc.

A gate mask layer filling a remaining portion of the gate trench may be formed on the gate insulation pattern 110 and the gate electrode 112. In addition, an upper portion of the gate mask layer may be planarized to form a gate mask 114. The gate mask layer may include silicon nitride by, for example, a CVD process.

Accordingly, the gate structure 116 including the gate insulation pattern 110, the gate electrode 112 and the gate mask 114, sequentially stacked in the gate trench, may be formed.

Depending on the arrangement of the gate trenches, the gate structure 116 may extend in the first direction, and a plurality of the gate structures 116 may be formed along the second direction. The gate structure 116 may be buried or embedded in an upper portion of the active pattern 105. An upper portion of the active pattern 105 may include a central portion between the two gate structures 116 and two peripheral portions adjacent to the two gate structures 116. The central portion of the active pattern 105 may be disposed between the two peripheral portions.

An ion-implantation process may be performed to form a first impurity region 107 and a second impurity region 109 at the upper portions of the active pattern. For example, the first impurity region 107 may be formed at the central portion of the active pattern 105, and the second impurity regions 109 may be formed at the peripheral portions of the active pattern 105.

In an example embodiment of the inventive concept, a metal layer may be formed to cover the active patterns 105. In addition, a thermal treatment may be performed to form a silicide layer including a metal silicide from upper portions of the impurity regions 107 and 109. In an example embodiment of the inventive concept, a first silicide layer and a second silicide layer may be formed on the first impurity region 107 and the second impurity region 109, respectively.

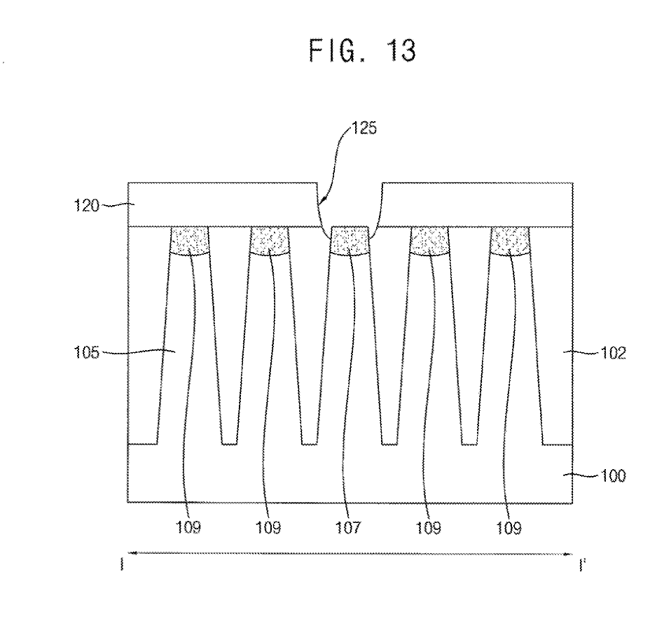

Referring to FIGS. 13 to 15, a first insulating interlayer 120 covering the active patterns 105 and the isolation layer 102 may be formed on the isolation layer 102 and the first and second impurity regions 107 and 109. The first insulating interlayer 120 may include a silicon oxide such as PEOX, TEOS, silicate glass, etc., or a low-k oxide such as siloxane or silsesquioxane by a CVD process or a spin coating process.

In an example embodiment of the inventive concept, an etch-stop layer may be further formed on the active patterns 105 and the isolation layer 102 before forming the first insulating interlayer 120. The etch-stop layer may include silicon nitride or silicon oxynitride.

The first insulating interlayer 120 may be partially etched to form a groove 125 through which the first impurity regions 107 may be exposed. The groove 125 may extend in the second direction indicated in FIG. 5 or FIG. 9. In addition, the plurality of first impurity regions 107 included in the different active patterns 105 may be exposed through the groove 125. A plurality of the grooves 125 may be formed along the first direction.

In an example embodiment of the inventive concept, a portion of the isolation layer 102 exposed through the groove 125 may also be partially removed such that an exposed area of the first impurity region 107 may be increased.

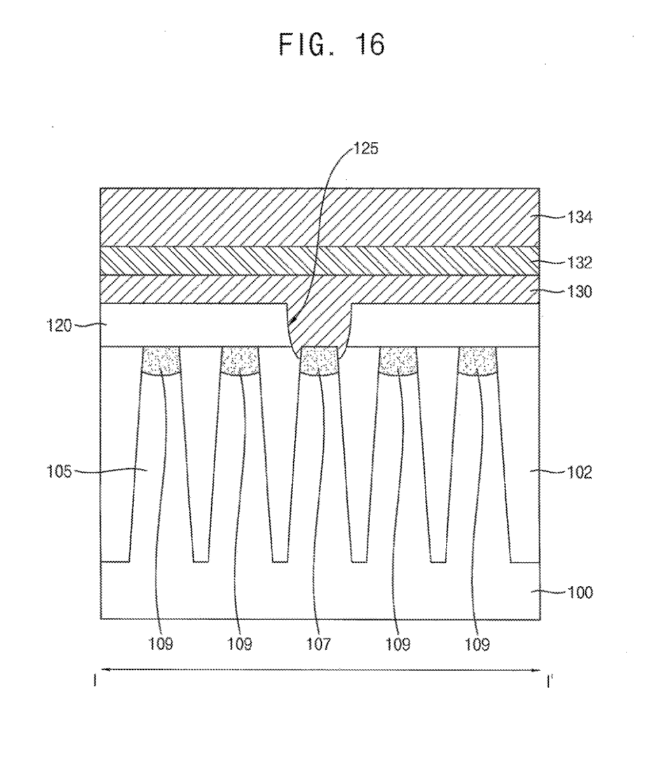

Referring to FIGS. 16 to 18, a first conductive layer 130 filling the groove 125 may be formed on the first insulating interlayer 120. A barrier conductive layer 132 and a second conductive layer 134 may be sequentially formed on the first conductive layer 130.

The first conductive layer 130 may include, for example, doped polysilicon. The barrier conductive layer 132 may include a metal nitride or a metal silicide nitride. The second conductive layer 134 may be formed using a metal. The first conductive layer 130, the barrier conductive layer 132 and the second conductive layer 134 may be formed by, for example, a sputtering process, a physical vapor deposition (PVD) process or an ALD process.

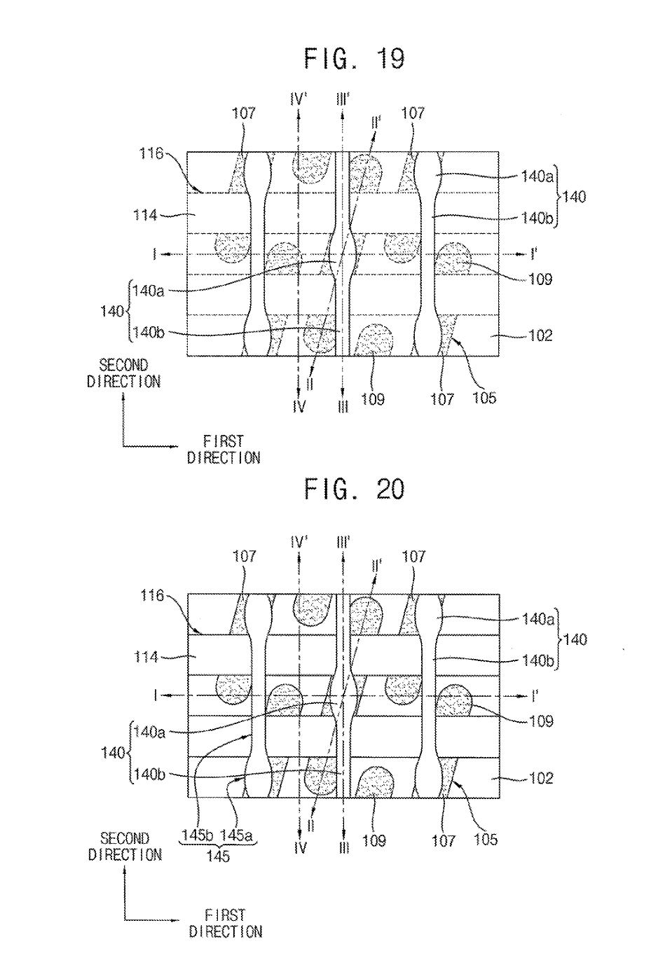

Referring to FIG. 19, a mask pattern 140 may be formed on the second conductive layer 134. The mask pattern 140 may include, for example, silicon nitride. For convenience of description, illustrations of the first insulating interlayer 120, the first conductive layer 130, the barrier conductive layer 132 and the second conductive layer 134 may be omitted in FIG. 19.

The mask pattern 140 may extend in the second direction, and a plurality of the mask patterns 140 may be formed along the first direction.

In an example embodiment of the inventive concept, the mask pattern 140 may include embossed portions or convex portions in plan view. For example, the mask pattern 140 may include first portions 140a and second portions 140b which may have different widths (e.g., widths in the first direction). The first portion 140a may be wider than the second portion 140b, and may correspond to the embossed portion or the convex portion of the mask pattern 140.

In an example embodiment of the inventive concept, the first portion 140a of the mask pattern 140 may be superimposed over the first impurity region 107. As illustrated in FIG. 19, the second portion 140b of the mask pattern 140 may be interposed between the second impurity regions 109 included in the different active patterns 105 in plan view.

In an example embodiment of the inventive concept, the mask pattern 140 may be formed by, for example, processes that will be illustrated with reference to FIGS. 35 to 47 to include the embossed portions or the convex portions.

In an example embodiment of the inventive concept, the mask pattern 140 may be formed by an etching process using a mask prepared from the processes that will be illustrated with reference to FIGS. 35 to 47.

Referring to FIGS. 20 to 23, a conductive line 145 may be formed by an etching process using the mask pattern 140.

In an example embodiment of the inventive concept, the second conductive layer 134, the barrier conductive layer 132 and the first conductive layer 130 may be sequentially etched using the mask pattern 140 as an etching mask. Accordingly, a first conductive pattern 131, a barrier conductive pattern 133 and a second conductive pattern 135 may be sequentially formed on the first impurity region 107. For convenience of description, an illustration of the first insulating interlayer 120 is omitted in FIG. 20.

Accordingly, the conductive line 145 extending in the second direction, and including the first conductive pattern 131, the barrier conductive pattern 133 and the second conductive pattern 135, may be formed on the first impurity region 107.

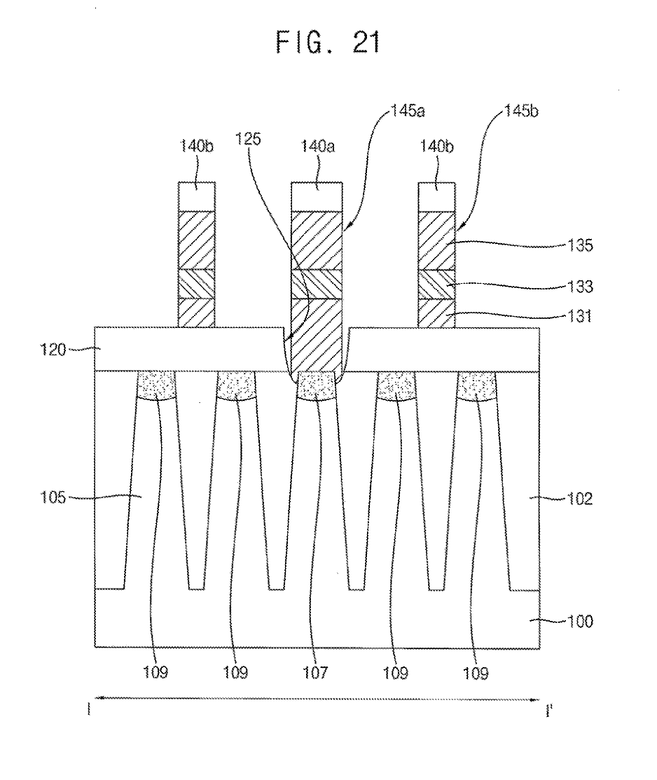

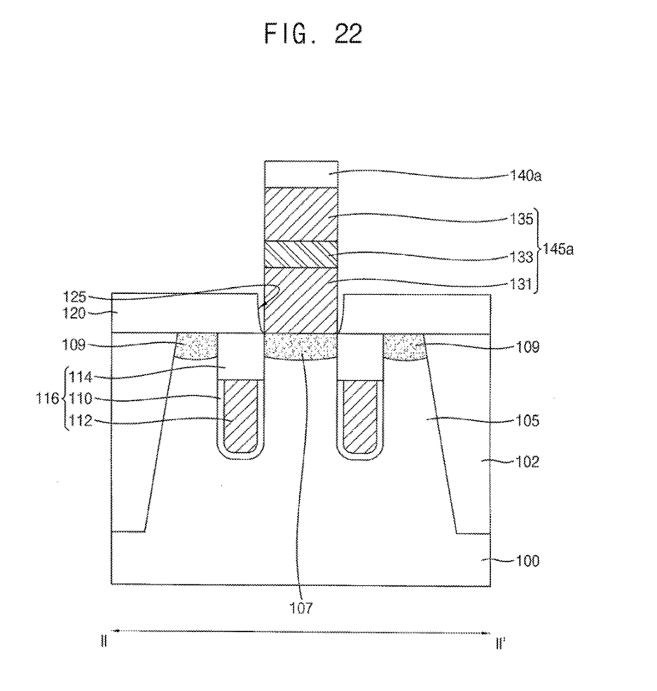

In an example embodiment of the inventive concept, the conductive line 145 may serve as a bit line. In an example embodiment of the inventive concept, as illustrated in FIGS. 21 and 22, the conductive line 145 may have a smaller width than that of the groove 125. In addition, a lower portion of the conductive line 145 may be inserted in the groove 125. A portion of the conductive line 145 (e.g., a portion of the first conductive pattern 131), formed in the groove 125 and connected to the first impurity region 107, may serve as a bit line contact.

According to the construction of the mask pattern 140 described above, the conductive line 145 may also include a first portion 145a having a relatively large width and a second portion 145b having a relatively small width.

The first portion 145a may be in contact with and/or electrically connected to the first impurity region 107. In an example embodiment of the inventive concept, a pair of second impurity regions 109 may be exposed around a second portion 145b. The second portion 145b may have the relatively small width so that an exposed area of the second impurity region 109 may be increased.

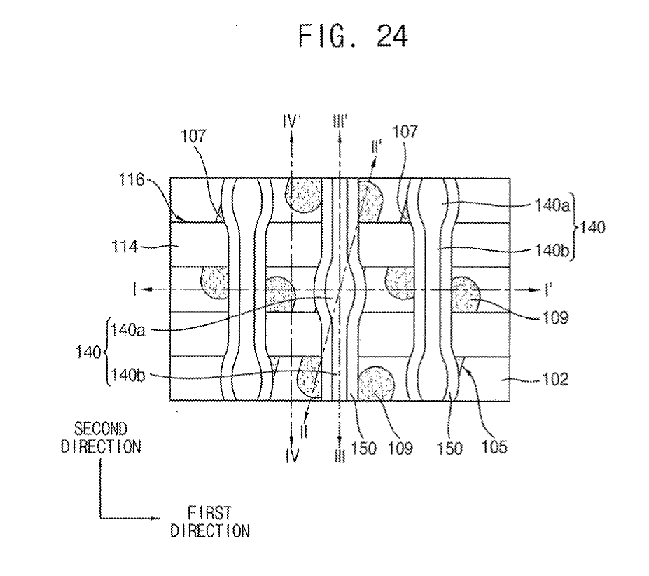

Referring to FIGS. 24 to 27, a spacer 150 may be formed on sidewalls of the conductive line 145 and the mask pattern 140.

A spacer layer covering the conductive line 145 and the mask pattern 140 may be formed, for example, on the first insulating interlayer 120. The spacer layer may be anisotropically etched to form the spacer 150. The spacer layer may include, for example, silicon nitride disposed by a CVD process or an ALD process.

Referring to FIGS. 28 to 30, a second insulating interlayer 160 filling spaces between the conductive lines 145 may be formed on the first insulating interlayer 120. The second insulating interlayer 160 may fill a remaining portion of the groove 125.

In an example embodiment of the inventive concept, the second insulating interlayer 160 may be formed to cover the mask pattern 140, and then an upper portion of the second insulating interlayer 160 may be planarized by a CMP process such that a top surface of the mask pattern 140 may be exposed. The second insulating interlayer 160 may include a silicon oxide substantially the same as or similar to that of the first insulating interlayer 120.

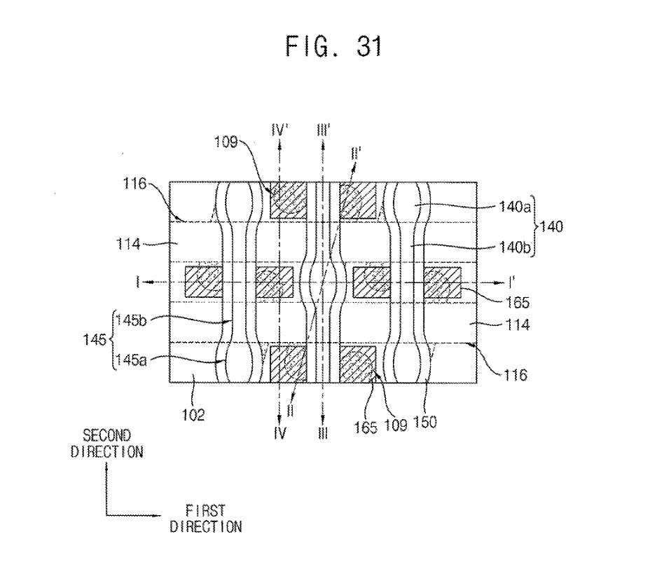

Referring to FIGS. 31 to 34, a conductive contact 165 may be formed through the second and first insulating interlayers 160 and 120 to be electrically connected to the second impurity region 109.

In an example embodiment of the inventive concept, the second and first insulating interlayers 160 and 120 may be partially etched to form a contact hole through which the second impurity region 109 (or the second silicide layer) may be exposed.

In an example embodiment of the inventive concept, the contact hole may be self-aligned (e.g., aligned) with the spacer 150. In this case, a sidewall of the spacer 150 may be exposed through the contact hole.

In an example embodiment of the inventive concept, the contact hole may be adjacent to the second portion 145b of the conductive line 145 having the relatively small width. Thus, an area of a second impurity region 109 exposed by the contact hole may be increased. It is understood that a plurality of contact holes may be formed. For example, two contact holes, one on each side of a second portion 145b of a conductive line 145, may be formed at each second portion 145b of a conductive line 145.

A contact conductive layer may be formed to fill the contact holes. In addition, an upper portion of the contact conductive layer may be planarized by a CMP process until the top surface of the mask pattern 140 may be exposed to form the conductive contact 165. Thus, the conductive contact 165, formed of the planarized contact conductive layer, may be electrically connected to the second impurity region 109 in each contact hole.

The contact conductive layer may include a metal such as copper, tungsten, aluminum, etc., and may be formed by a sputtering process, a PVD process, an ALD process, a CVD process, etc. In an example embodiment of the inventive concept, the contact conductive layer may be formed by a plating process. For example, a copper seed layer may be formed on an inner wall of the contact hole, and the contact conductive layer may be formed from the seed layer from an electroplating process. In an example embodiment of the inventive concept, the contact conductive layer may be formed by an electroless plating process such as a chemical plating process.

In an example embodiment of the inventive concept, a barrier conductive layer including, for example, titanium or titanium nitride, may be formed on an inner wall of the contact hole before forming the contact conductive layer.

As described above, the first portion 145a of the conductive line 145, which may have a relatively large width, may be electrically connected to the first impurity region 107. The conductive contact 165 may be aligned with the second portion 145b of the conductive line 145, which may have a relatively small width, to be electrically connected to the second impurity region 109.

Therefore, an electrical resistance through the first and second impurity regions 107 and 109 may be reduced so that operational properties of the semiconductor device may be enhanced.

FIGS. 35 to 47 are top plan views and cross-sectional views of a mask fabricating process for forming a conductive line, according to an example embodiment of the inventive concept. For example, FIGS. 35 to 47 illustrate processes of forming the mask pattern 140 in FIG. 19 or a mask for forming the conductive line in FIG. 20.

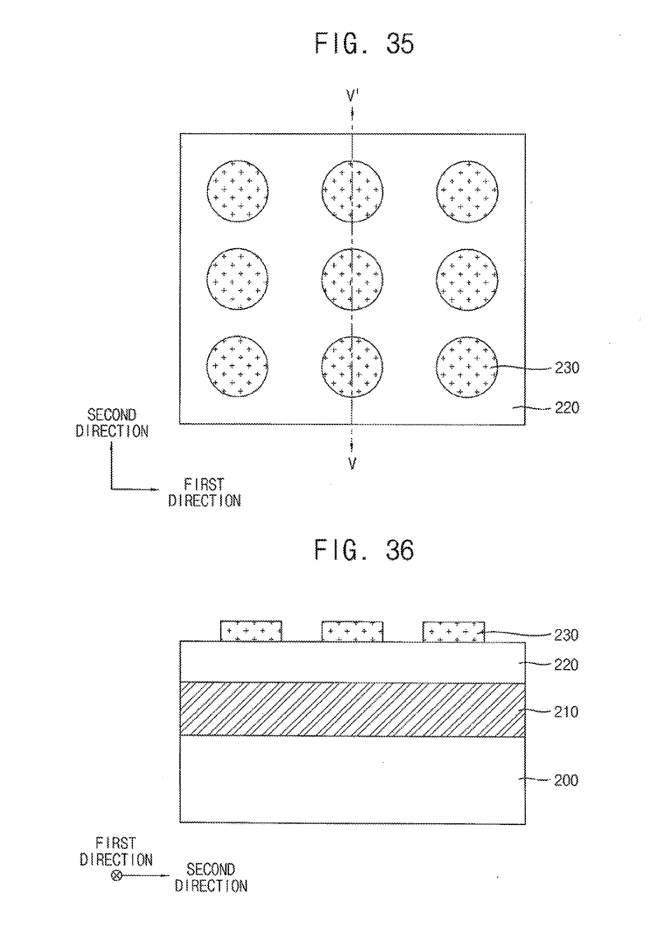

In more detail, FIGS. 35, 37, 39, 41, 43, 45, 46 and 47 are top plan views illustrating stages of the mask fabricating process. FIGS. 36, 38, 40, 42 and 44 are cross-sectional views taken along a line V-V′ indicated in the top plan views.

Referring to FIGS. 35 and 36, a first sacrificial layer 210 and a second sacrificial layer 220 may be formed on an object layer 200. In addition, photoresist patterns 230 may be formed on the second sacrificial layer 220.

The object layer 200 may be, for example, a mask layer for forming the mask pattern 140 of FIG. 19. However, the object layer 200 may also be the second conductive layer 134 of FIGS. 16 to 18.

The first sacrificial layer 210 may include, for example, a silicon-based or carbon-based spin-on hardmask (SOH) material. The second sacrificial layer 220 may include, for example, silicon oxynitride.

The photoresist pattern 230 may have, for example, a cylindrical shape, and may be formed on the second sacrificial layer 220 at regular intervals along first and second directions.

The first and second directions may be parallel to a plane of a top surface of the object layer 200. In addition, the first and second directions may be perpendicular to each other.

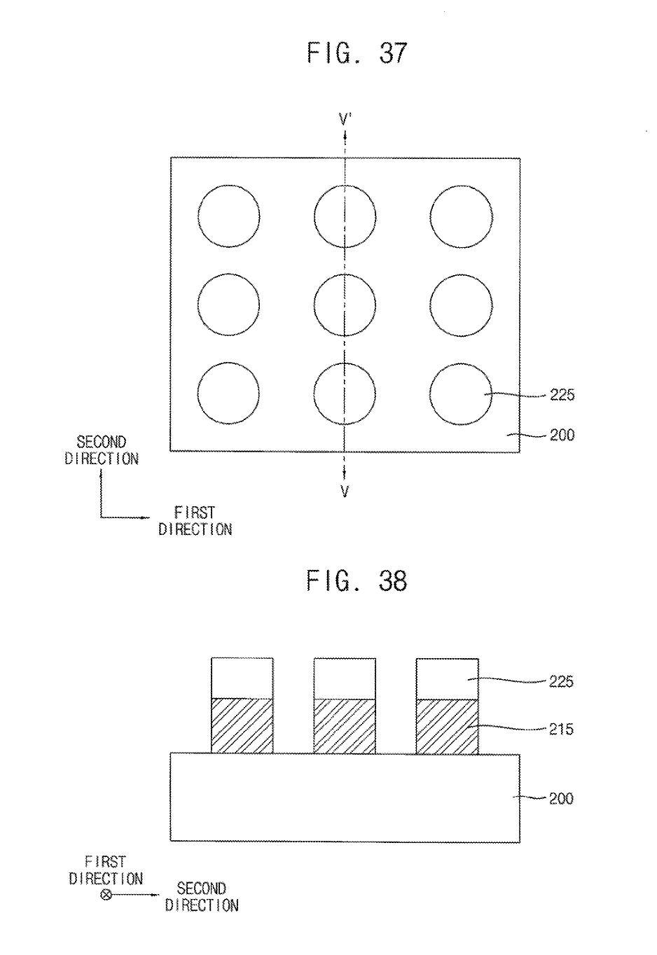

Referring to FIGS. 37 and 38, the second and first sacrificial layers 220 and 210 may be partially removed using the photoresist pattern 230 as an etching mask. Accordingly, a first sacrificial pattern 215 and a second sacrificial pattern 225 may be formed on the object layer 200. The photoresist pattern 230 may be removed by, for example, an ashing process and/or a strip process.

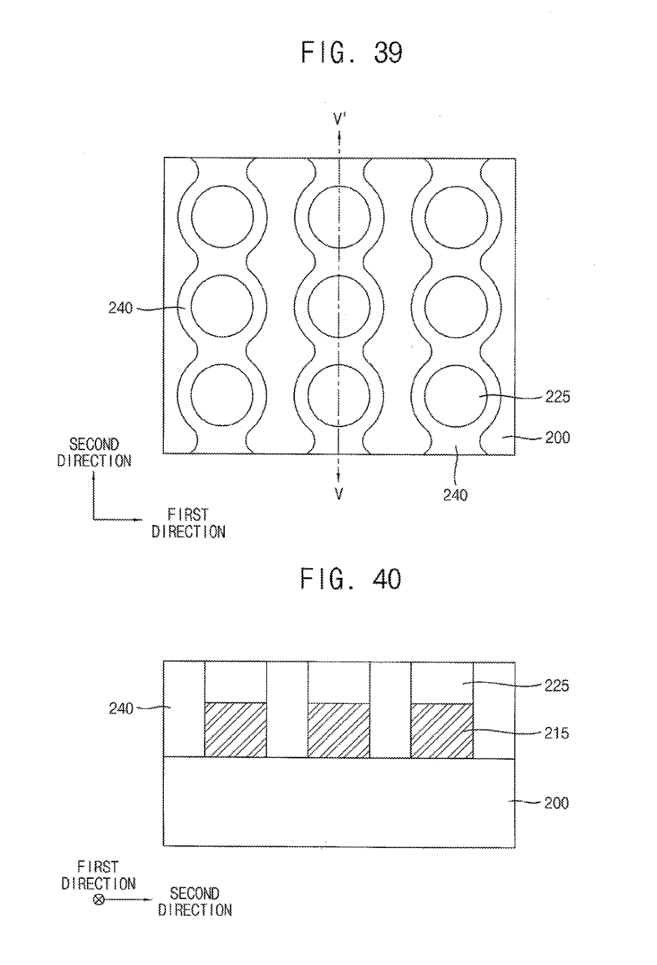

Referring to FIGS. 39 and 40, a first spacer 240 may be formed on sidewalls of the first and second sacrificial patterns 215 and 225.

In an example embodiment of the inventive concept, a first spacer layer covering the first and second sacrificial patterns 215 and 225 may be formed on the object layer 200. Upper and lower portions of the first spacer layer may be removed by an etch-back process to form the first spacer 240.

The first spacer 240 may extend continuously in the second direction, and a plurality of the first spacers 240 may be spaced apart from each other in the first direction. The first spacer 240 may include an oxide-based material, for example, an ALD oxide.

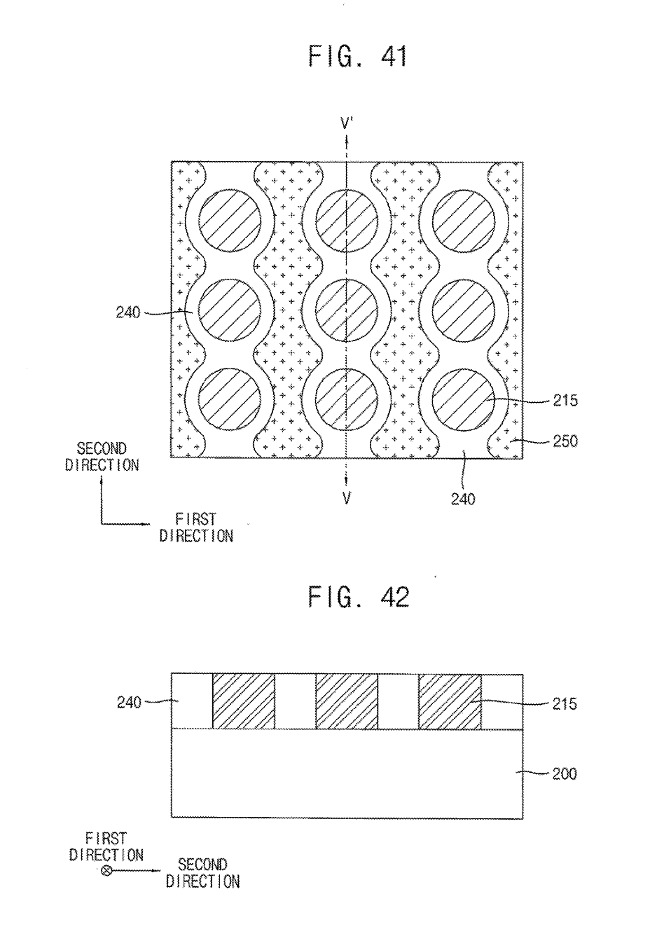

Referring to FIGS. 41 and 42, a first mask 250 may be formed between the neighboring first spacers 240.

In an example embodiment of the inventive concept, a first mask layer that fills spaces between the neighboring first spacers 240 may be formed on the object layer 200, the first spacer 240 and the second sacrificial pattern 225. Upper portions of the first mask layer and the first spacer 240 may be planarized until a top surface of the first sacrificial pattern 215 may be exposed to form the first mask 250.

The planarization process may include, for example, an etch-back process or a CMP process. The second sacrificial pattern 225 may be removed by the planarization process.

In an example embodiment of the inventive concept, the first mask layer may include a silicon-based material, for example, polysilicon or amorphous silicon.

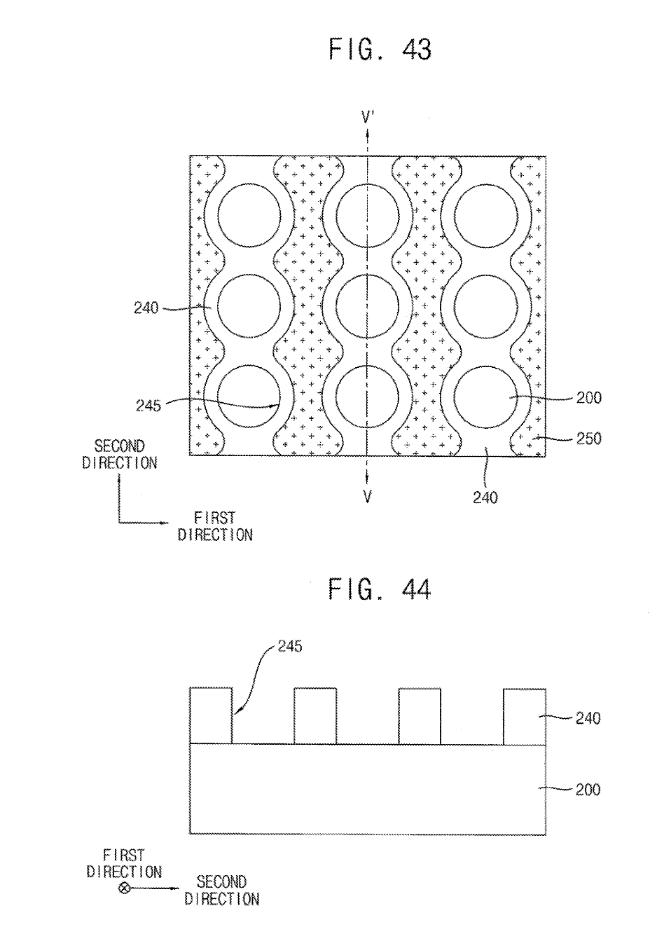

Referring to FIGS. 43 and 44, the first sacrificial pattern 215 may be removed by, for example, an ashing process. A first opening 245 may be defined by a space from which the first sacrificial pattern 215 is removed. The top surface of the object layer 200 may be exposed through the first opening 245.

Referring to FIG. 45, the first spacer 240 may be removed. The first spacer 240 may be removed, for example, using an etchant solution including, for example, fluoric acid, or an etching gas including, for example, an alkyl fluoride having an etching selectivity for the oxide-based material.

A space from which the first spacer 240 is removed may be merged with the first openings 245 such that a second opening 247 may be formed. The second opening 247 may extend in the second direction, and a plurality of the second openings 247 may be separated along the first direction by the first masks 250.

In an example embodiment of the inventive concept, the first sacrificial pattern 215 may be removed after removing the first spacer 240.

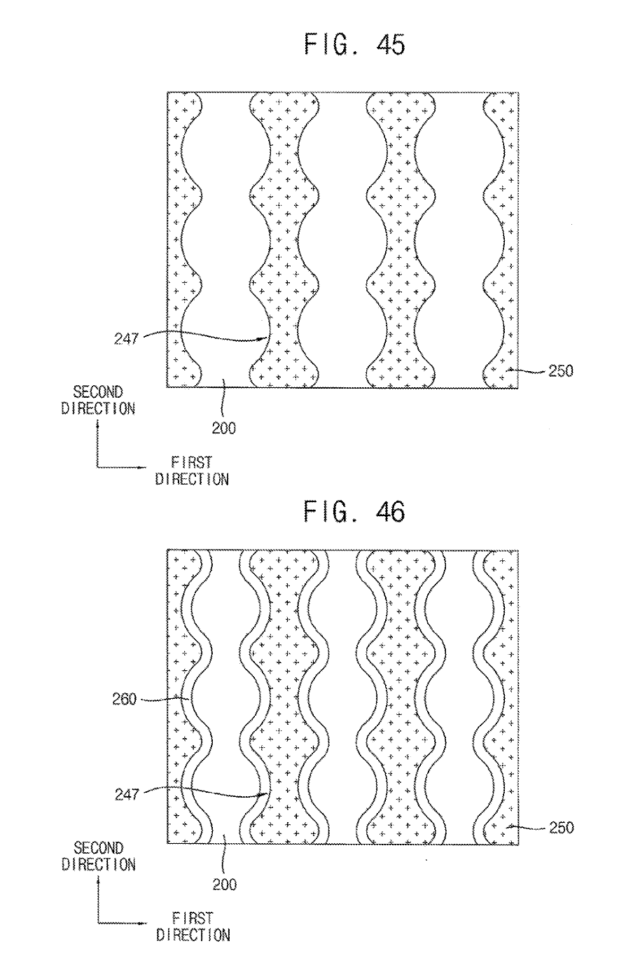

Referring to FIG. 46, a second spacer 260 may be formed along a sidewall of the second opening 247.

For example, a second spacer layer may be formed on the top surface of the object layer 200 and on surfaces of the first masks 250. Upper and lower portions of the second spacer layer may be removed by, for example, an etch-back process. Accordingly, the second spacer 260 may selectively remain on the sidewall of the second opening 247. The second spacer 260 may include, for example, an ALD oxide substantially the same as or similar to that of the first spacer 240.

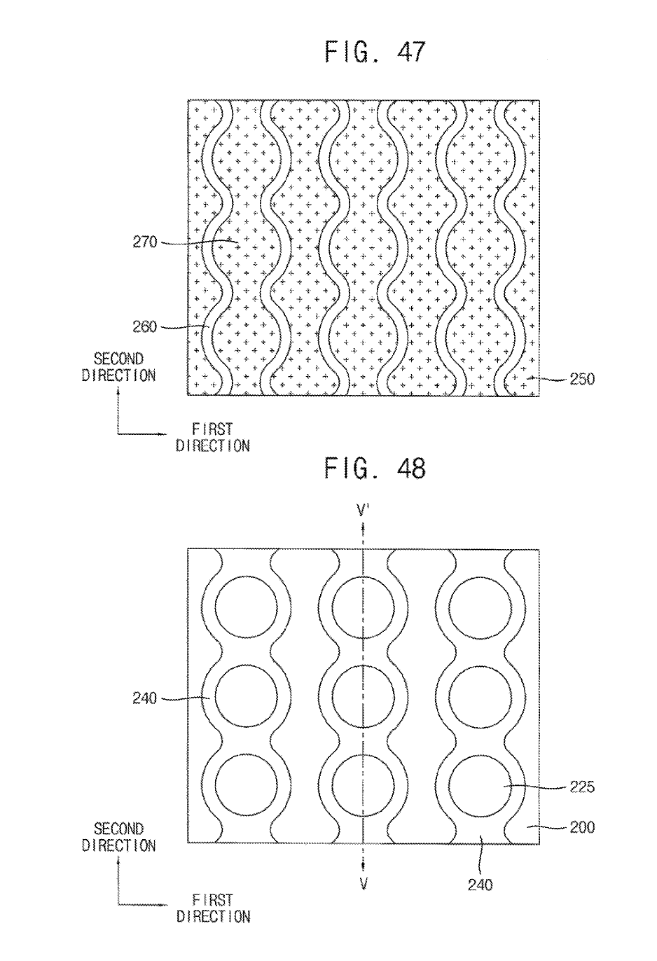

Referring to FIG. 47, a second mask 270 may be formed in the second opening 247 which may have a reduced width by the second spacer 260.

For example, a second mask layer, which fills the second openings 247, may be formed on the first mask 250 and the second spacer 260. An upper portion of the second mask layer may be planarized by a CMP process until the second spacer 260 may be exposed to form the second mask 270 between the first masks 250. The second mask 270 and the first mask 250 may be separated by the second spacer 260.

The second mask layer may include a silicon-based material substantially the same as or similar to that of the first mask layer.

The second spacer 260 may be subsequently removed, and the object layer 200 may be patterned using the first and second masks 250 and 270 as an etching mask. According to the processes described above, the first and second masks 250 and 270 may be formed to have a structure having a width which may increase and decrease repeatedly along the second direction. The conductive line 145, according to example embodiment of the inventive concept, may be achieved by an etching process using the first and second masks 250 and 270.

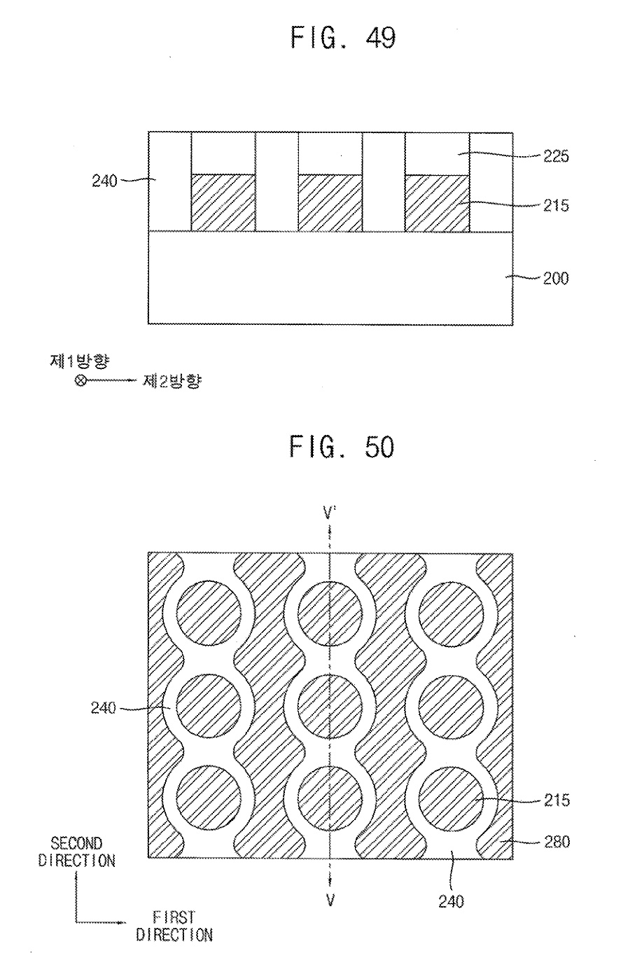

FIGS. 48 to 53 are top plan views and cross-sectional views of a mask fabricating process for forming a conductive line, according to an example embodiment of the inventive concept. For example, FIGS. 48, 50 and 52 are top plan views illustrating stages of the mask fabricating process. FIGS. 49, 51 and 53 are cross-sectional views taken along a line V-V′ indicated in FIGS. 48, 50 and 52, respectively.

A detailed description of processes substantially the same as or similar to those illustrated with reference to FIGS. 35 to 47 may be omitted hereinafter. The first and second directions, as described in FIGS. 35 to 47, may also apply to FIGS. 48 to 53.

Referring to FIGS. 48 and 49, processes substantially the same as or similar to those illustrated in FIGS. 35 to 40 may be performed. Accordingly, sacrificial patterns including a first sacrificial pattern 215 and a second sacrificial pattern 225 may be formed on an object layer 200. A first spacer 240 extending in the second direction along sidewalls of the sacrificial patterns may be formed.

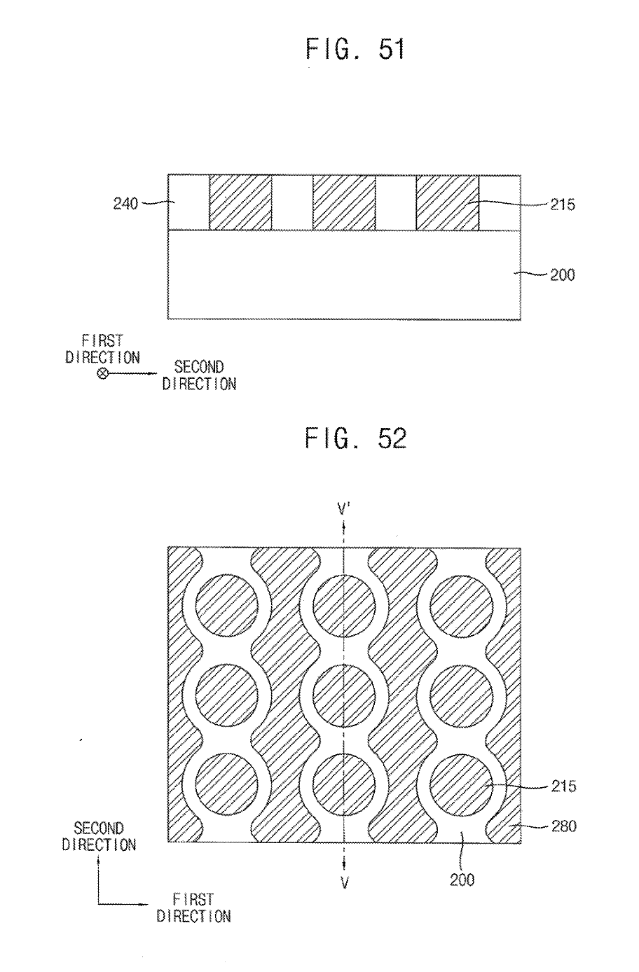

Referring to FIGS. 50 and 51, a mask layer filling a space between the neighboring first spacers 240 may be formed on the object layer 200 and the second sacrificial pattern 225. For example, the mask layer may include an SOH material substantially the same as or similar to that of the first sacrificial pattern 215.

An upper portion of the mask layer may be planarized by, for example, a CMP process until a top surface of the first sacrificial pattern 215 may be exposed. Thus, a mask pattern 280 may be formed in the space between the neighboring first spacers 240. The second sacrificial pattern 225 may be removed by the planarization process, and an upper portion of the first spacer 240 may be also removed.

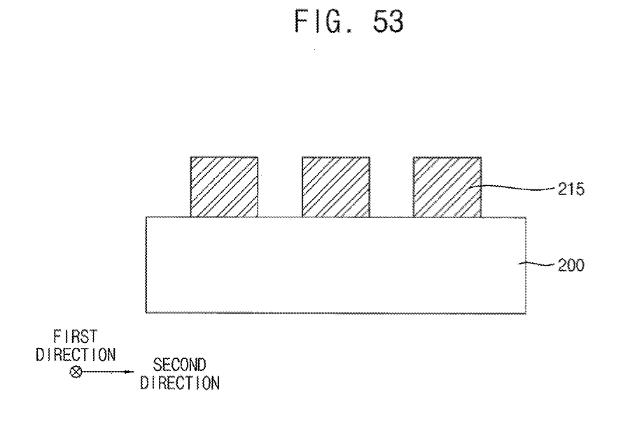

Referring to FIGS. 52 and 53, the first spacer 240 may be removed. The first spacer 240 may be removed using an etchant solution or an etching gas that may have an etching selectivity for an oxide-based material. The object layer 200 may be exposed through a space from which the first spacer 240 is removed.

Subsequently, the object layer 200 may be patterned using the first sacrificial pattern 215 and the mask pattern 280 as an etching mask.

In an example embodiment of the inventive concept, a portion of the object layer 200 patterned from the mask pattern 280 may serve as the conductive line 145 illustrated in FIGS. 1 to 4. The conductive line 145 may include the first portion 145a and the second portion 145b having different widths depending on the features of the mask pattern 280.

In an example embodiment of the inventive concept, a portion of the object layer 200 patterned from the first sacrificial pattern 215 may serve as the conductive contact 165 illustrated in FIGS. 1 to 4.

According to example embodiment of the inventive concept as described above, the conductive line 145 and the conductive contact 165 may be formed concurrently using a single patterning process. Thus, the number of steps or stages of the patterning process may be reduced. Accordingly, the manufacturing efficiency of the semiconductor device may be increased and the process productivity may be increased.

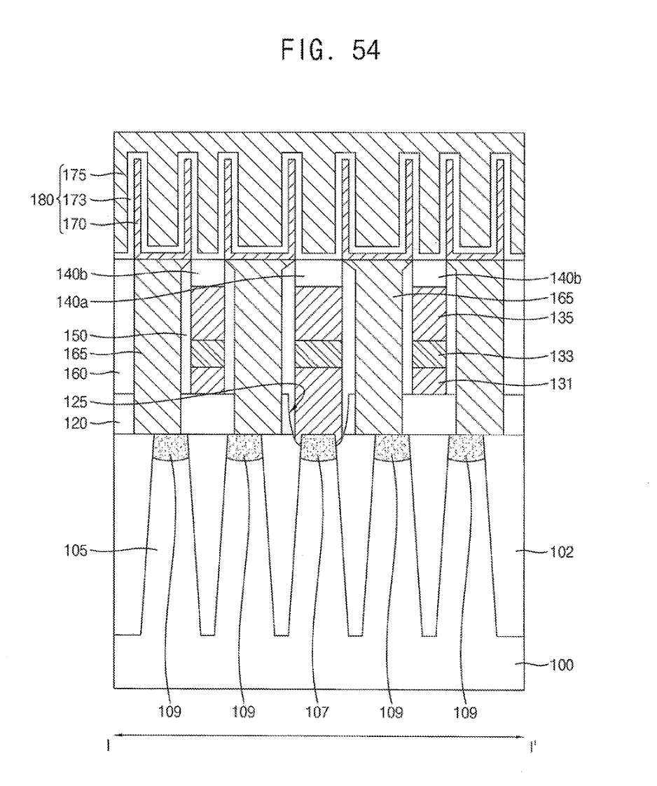

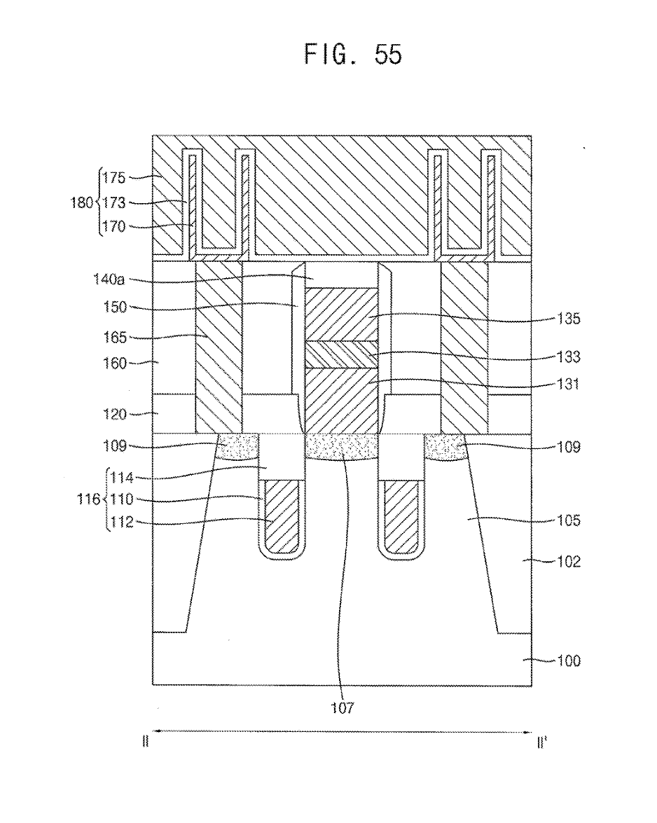

FIGS. 54 and 55 are cross-sectional views of a semiconductor device, according to an example embodiment of the inventive concept. In more detail, FIGS. 54 and 55 are cross-sectional views taken along lines I-I′ and II-II′, respectively, indicated in FIG. 1.

FIGS. 54 and 55 illustrate a memory device including the BCAT structure and the conductive line structure illustrated in FIGS. 1 to 4. Detailed descriptions of elements and/or features of the semiconductor device that are the same or similar to those illustrated in the semiconductor device of FIGS. 1 to 4 may be omitted for brevity.

Referring to FIGS. 54 and 55, the semiconductor device may include a capacitor 180 electrically connected to the conductive contact 165. The capacitor 180 may serve as a data storage unit. In this case, the semiconductor device may be a dynamic random-access memory (DRAM) device including the BCAT structure.

The capacitor 180 may include a lower electrode 170, a dielectric layer 173 and an upper electrode 175 sequentially stacked on the conductive contact 165.

The lower electrode 170 may contact the conductive contact 165, and may include a metal such as titanium or tantalum, and/or a nitride of the metal included in the lower electrode 170. The lower electrode 170 may be disposed on each conductive contact 165, and may have, for example, a cup shape.

The dielectric layer 173 may include a high-k metal oxide such as zirconium oxide, hafnium oxide and/or aluminum oxide. The dielectric layer 170 may extend conformally along surfaces of a plurality of the lower electrodes 170.

The upper electrode 175 may include a metal such as titanium or tantalum, and/or a nitride of the metal included in the upper electrode 175. The upper electrode 175 may be disposed on the dielectric layer 173, and may cover the plurality of the lower electrodes 170. The upper electrode 175 may serve as a common plate electrode for a plurality of the capacitors 180.

In an example embodiment of the inventive concept, a passivation layer including silicon nitride or silicon oxynitride may be further formed on the upper electrode 175.

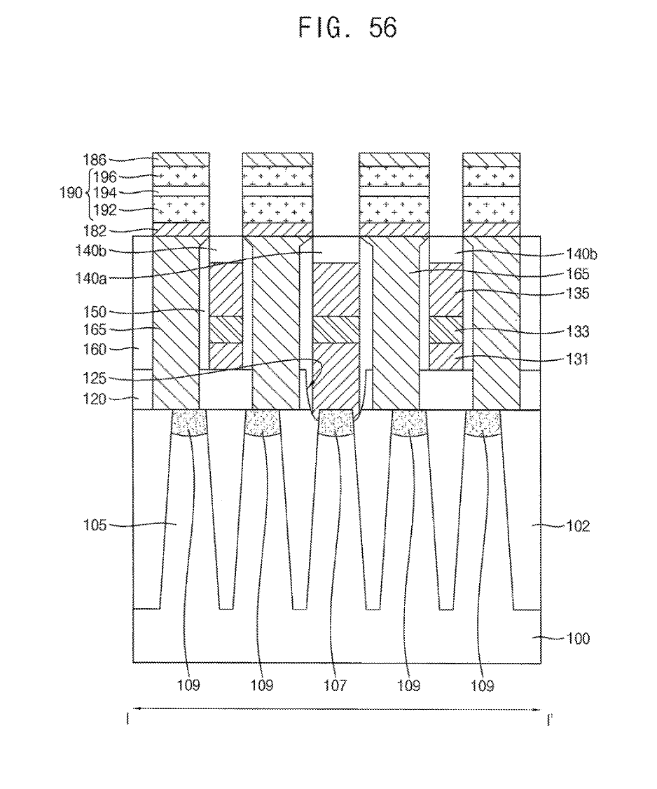

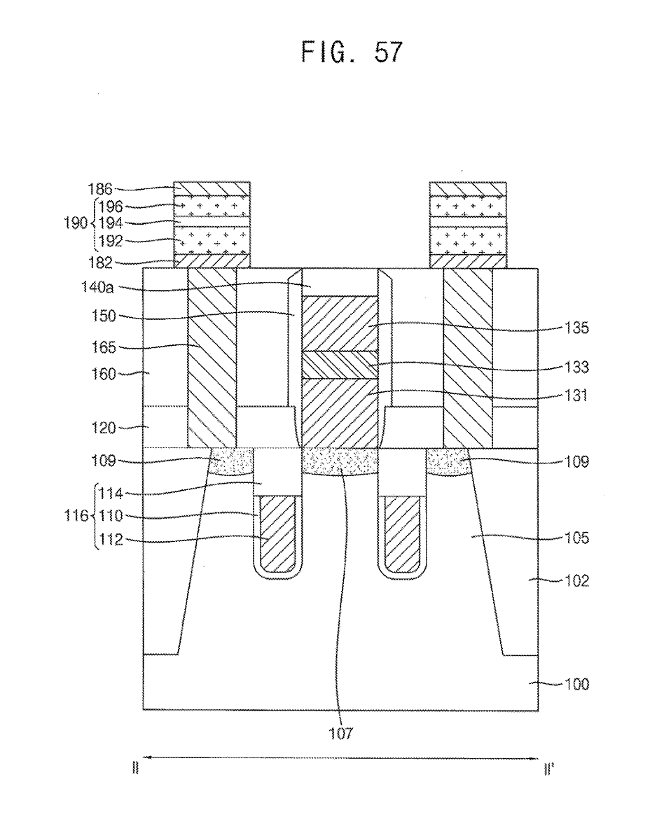

FIGS. 56 and 57 are cross-sectional views of a semiconductor device, according to an example embodiment of the inventive concept. Specifically, FIGS. 56 and 57 are cross-sectional views taken along lines I-I′ and II-II′, respectively, indicated in FIG. 1.

FIGS. 56 and 57 illustrate a memory device including the BCAT structure and the conductive line structure included in the semiconductor device of FIGS. 1 to 4. A detailed description of elements and/or features included in the semiconductor device described with reference to FIGS. 1 to 4 may be omitted for brevity.

Referring to FIGS. 56 and 57, the semiconductor device may include a magnetic tunnel junction (MTJ) structure 190 on the conductive contact 165. The MTJ structure 190 may serve as a data storage unit. In this case, the semiconductor device may be a magnetic random-access memory (MRAM) device including the BCAT structure.

In an example embodiment of the inventive concept, a lower electrode 182 may be disposed on each conductive contact 165, and an upper electrode 186 may be disposed over the lower electrode 182. The MTJ structure 190 may be interposed between the lower electrode 182 and the upper electrode 186. The lower and upper electrodes 182 and 186 may include a metal such as titanium or tantalum, and/or a nitride of the metal used in the respective lower and upper electrodes 182 and 186.

The MTJ structure 190 may include a fixed layer 192, a tunnel barrier 194 and a free layer 196.

The fixed layer 192 may be configured to have a fixed magnetization direction. The free layer 196 may have a parallel or anti-parallel magnetization direction with respect to that of the fixed layer 192. The fixed layer 192 and the free layer 196 may include a ferromagnetic metal such as cobalt, iron, nickel and/or platinum. The tunnel barrier 194 may include, for example, at least one of magnesium oxide, titanium oxide, aluminum oxide, magnesium zinc oxide or magnesium boron oxide.

According to an example embodiment of the inventive concept of the present inventive concept, a conductive line (e.g., a bit line) may include first portions having a relatively large width, and second portions having a relatively small width. A portion of an active pattern, on which a conductive contact is disposed, may be exposed near the second portion of the conductive line. The conductive line may be connected to the active pattern via the first portion having the relatively large width. Thus, contact areas beween the conductive contact and the conductive line may be increased. Accordingly, operational properties of a semiconductor device may be enhanced when connecting the conductive line to the active pattern using the first portion. It is understood that each of a plurality of first portions of a conductive line of a semiconductor device may be connected to an active pattern of the semiconductor device. The conductive lines, according to an example embodiment of the inventive concept, may be utilized as bit lines of various semiconductor devices including, for example, a DRAM device, an MRAM device, etc.

While the inventive concept has been particularly shown and described with reference to example embodiments thereof, it will be apparent to those of ordinary skill in the art that various changes in form and detail may be made therein without departing from the spirit and scope of the inventive concept.

What is claimed is:

1. A semiconductor device, comprising:
an active pattern;
a gate structure disposed on the active pattern;
a first source or drain region and a second source or drain region formed at upper portions of the active pattern, wherein the first source or drain region and the second source or drain region are each disposed adjacent to the gate structure, wherein the gate structure is disposed between the first source or drain region and the second source or drain region;
a conductive line electrically connected to the first source or drain region, the conductive line including a first portion and a second portion, wherein a width of the first portion is greater than a width of the second portion, wherein the width of the first and second portions of the conductive line is measured along a first direction in plan view; and
a conductive contact electrically connected to the second source or drain region.

2. The semiconductor device of claim 1, wherein the first portion of the conductive line overlaps the first source or drain region in plan view.

3. The semiconductor device of claim 1, further comprising a plurality of conductive lines and a plurality of active patterns,
wherein at least one of the plurality of conductive lines extends in a second direction that crosses the first direction in plan view, and each of the plurality of conductive lines includes a first portion and a second portion, the first portion being wider than the second portion in the first direction, and
wherein at least one of the plurality of active patterns extends along a third direction, the third direction forming an acute angle with respect to the first or second directions, and wherein the plurality of active patterns are spaced apart from each other.

4. The semiconductor device of claim 3, wherein a first portion of one of the plurality of conductive lines faces a second portion of another conductive line, of the plurality of conductive lines, in the first direction.

5. The semiconductor device of claim 3, wherein each of two neighboring active patterns of the plurality of active patterns includes a second source or drain region, and the second portion of one of the plurality of conductive lines is disposed between the second source or drain regions of the neighboring active patterns.

6. The semiconductor device of claim 3, further comprising a plurality of gate structures, wherein at least one of the plurality of gate structures extends in the first direction, and the plurality of the gate structures is arranged along the second direction, wherein at least one of the plurality of gate structures is buried in each of the plurality of active patterns.

7. The semiconductor device of claim 1, further comprising a spacer disposed on a sidewall of the conductive line.

8. The semiconductor device of claim 7, wherein the conductive contact is in contact with a sidewall of the spacer.

9. The semiconductor device of claim 1, further comprising a capacitor or a magnetic tunnel junction (MTJ) structure disposed on the conductive contact.

10. A semiconductor device, comprising:
a substrate;
an isolation layer disposed on the substrate;
a plurality of active patterns protruding from the substrate, the active patterns of the plurality of active patterns being spaced apart from each other by the isolation layer;
a plurality of gate structures buried in the isolation layer and buried in the active patterns, the plurality of gate structures extending in a first direction parallel to a plane of a top surface of the substrate;
first source or drain regions and second source or drain regions formed at upper portions of the plurality of active patterns, the first source or drain regions and the second source or drain regions being separated from each other by the plurality of gate structures;
a plurality of conductive lines electrically connected to the first source or drain regions, the plurality of conductive lines extending in a second direction parallel to the top surface of the substrate, wherein the second direction crosses the first direction, and each of the plurality of conductive lines includes enlarged portions and straight portions, wherein the enlarged portions protrude in the first direction and are wider than the straight portions in the first direction; and
a plurality of conductive contacts electrically connected to the second source or drain regions of the plurality of active patterns, the plurality of conductive contacts being disposed adjacent to the straight portions of the plurality of conductive lines.

11. The semiconductor device of claim 10, wherein the enlarged portions included in different conductive lines of the plurality of conductive lines are arranged in a zigzag configuration in plan view.

12. The semiconductor device of claim 10, wherein the plurality of conductive lines are electrically connected to the first source or drain regions using the enlarged portions.

13. The semiconductor device of claim 10, wherein the plurality of conductive contacts partially overlap corresponding second source or drain regions in plan view.

14. The semiconductor device of claim 10, wherein at least one of the plurality of conductive contacts is interposed between the enlarged portion of a first of the plurality of conductive lines and the linear portion of a second of the plurality of conductive lines.

15. The semiconductor device of claim 10, wherein each of the plurality of conductive lines includes a conductive pattern and a mask pattern sequentially stacked on at least one of the plurality of active patterns.

16. A semiconductor device, comprising:
an active pattern, wherein the active pattern includes a first source or drain region and at least two second source or drain regions, wherein the first source or drain region is disposed between the at least two second source or drain regions;
a gate structure disposed on the active pattern, wherein the first source or drain region and one of the at least two second source or drain regions are separated from each other by the gate structure;
a conductive line electrically connected to the first source or drain region, wherein the conductive line includes first portions and second portions, the first portions being wider than the second portions in a first direction in plan view, wherein the first and second portions of the conductive line are alternately arranged along a second direction that crosses the first direction in plan view; and
a conductive contact electrically connected to one of the at least two second source or drain regions.

17. The semiconductor device of claim 16, wherein the first source or drain region is electrically connected to at least one of the first portions of the conductive line.

18. The semiconductor device of claim 16, wherein the conductive contact is electrically connected to the one of the at least two second source or drain regions through a portion of the one of the at least two second source or drain regions that does not overlap the conductive contact in plan view.

19. The semiconductor device of claim 16, further comprising at least two conductive contacts, wherein one of the second portions of the conductive line is disposed between the at least two conductive contacts.

20. The semiconductor device of claim 16, wherein a first insulating interlayer is disposed between the active pattern and the conductive line, and wherein the conductive line and the first source or drain region are electrically connected to each other through a groove that penetrates the first insulating layer.
